(19) United States
(12) Patent Application Publication
(10) Pub. No.: US 2011/0155056 A1
(43) Pub. Date: Jun. 30, 2011

(54) FILM DEPOSITION APPARATUS

(75) Inventors: Hitoshi KATO, Iwate (JP); Manabu HONMA, Iwate (JP); Yasushi TAKEUCHI, Iwate (JP)

(73) Assignee: TOKYO ELECTRON LIMITED, TOKYO (JP)

(21) Appl. No.: 12/969,699

(22) Filed: Dec. 16, 2010

(30) Foreign Application Priority Data
Dec. 25, 2009 (JP) 2009-295226

(51) Int. Cl. C23C 16/458

(52) U.S. Cl. 118/719

(57) ABSTRACT

A film deposition apparatus has a vacuum chamber in which a turntable placing plural substrates is rotated, the plural substrates come into contact with plural reaction gases supplied to plural process areas and thin films are deposited on surfaces of the plural substrates, and has plural reaction gas supplying portions for supplying the plural processing gases, a separation gas supplying portion for supplying a separation gas and an evacuation mechanism for ejecting the plural processing gases and the separation gas, wherein the plural process areas includes a first process area for causing a first reaction gas to adsorb on the surfaces of the plural substrates, and a second process area, having an area larger than the first process area, for causing the first reaction gas having adsorbed the surfaces of the plural substrates and a second reaction gas to react, and depositing the films on the surfaces of the plural substrates.

### CROSS-REFERENCE TO RELATED APPLICATION

This application is based upon and claims the benefit of priority of Japanese Patent Application No. 2009-295226, filed on Dec. 25, 2009, the contents of which are incorporated herein by reference in their entirety.

### BACKGROUND OF THE INVENTION

1. Field of the Invention

This invention relates to a film deposition apparatus in which, in a vacuum chamber, a turntable on which plural substrates are placed is rotated, the substrates in sequence come into contact with reaction gases supplied to plural different process areas, and thin films are deposited on surfaces of the substrates.

2. Description of the Related Art

The following apparatus is known as one example of an apparatus carrying out vacuum processes such as a film deposition process, an etching process and so forth on a substrate such as a semiconductor wafer (referred to as “wafer” hereinafter). This apparatus is a so called minibatch-type apparatus in which placing tables for placing wafers are provided along a circumferential direction of a vacuum chamber, plural processing gas supplying portions are provided above the placing tables, and the vacuum processes are carried out while the plural wafers are placed on a turntable and are revolved. This apparatus is suitable for carrying out a method, for example, called ALD (Atomic Layer Deposition), MLD (Molecular Layer Deposition) or such, in which a first reaction gas and a second reaction gas are supplied to a wafer alternately and an atomic layer or a molecular layer is laminated.

In such an apparatus, it is required to separate the first and second reaction gases for preventing these gases from mixing on the wafer. For example, a patent document 1 (Korean publication No. 10-2009-0012396, the same hereinafter) describes the following configuration. In the configuration, gas supplying areas (gas supplying openings) are provided respectively for a first source gas and a second source gas at a gas blowout part like a showerhead provided to face a susceptor. Further, in order to prevent mixing of these source gases, a purge gas is supplied from between the first and second source gas supplying areas and from a center of the gas blowout part. Further, an evacuation groove portion provided to surround the susceptor is divided into two parts by a partition. Thus, the first source gas and the second source gas are ejected from mutually different evacuation groove portions respectively.

A patent document 2 (Japanese patent publication No. 2008-516428, the same hereinafter) describes the following configuration. In this configuration, above a chamber provided to face a substrate holder, an intake zone for supplying a first precursor materials gas, an evacuation area for ejecting the gas, an intake zone for supplying a second precursor materials gas and an evacuation area for ejecting the gas are supplied radially. In this example, by providing the evacuation areas respectively corresponding to the first and second precursor material gas intake zones, the first and second precursor material gases are separated. Further, separation of the first and second precursor material gases is attempted as a result of a purge gas being supplied between the adjacent precursor material gas intake zones.

In the above-mentioned configuration in which substrates are placed on the susceptor or such and the susceptor or such is rotated, a processing time becomes longer as an area of a process area is larger in a case where a rotation speed of the susceptor is fixed. Therefore, in a case where reaction speeds of the first and second reaction gases are different, a reaction progresses sufficiently by a reaction gas having a larger reaction speed, when the areas of the respective process areas are the same. However, a processing time is insufficient for a reaction gas having a smaller reaction speed, and the substrate may be moved to a next process area in a condition in which the reaction is insufficient. In the method of ALD or MLD, an adsorption reaction to a substrate surface by the first reaction gas and oxidation reaction of the first reaction gas having adsorbed on the substrate surface by the second reaction gas are alternately repeated many times, and the oxidation reaction requires a more time in comparison to the adsorption reaction of the first reaction gas. Therefore, when a next first reaction gas adsorption reaction is carried out in a condition in which oxidation reaction has not progressed sufficiently, a quality of a resulting film may degrade.

Such a situation can be improved by reducing the rotation speed for causing the reaction to progress sufficiently also for the gas having the smaller reaction speed, or increasing a flow rate of the reaction gas. However, such a method is not preferable in view of a throughput or saving the reaction gas amount. Further, in the configurations of the patent document 1 and the patent document 2, it is not considered to deposit a film satisfactory in quality in a condition in which plural gases having different reaction speeds are used and a revolution speed of the substrates is high. Therefore, the configurations of the patent document 1 and the patent document 2 may create a problem to be solved by the present invention described later.

Further, in the apparatuses of the patent document 1 and the patent document 2, the source gases or the precursor material gases are supplied toward the substrates on the lower side together with the purge gas from the gas supplying portions that are provided to face the susceptor or the substrate holder. Here, in order to separate the different source gases or such by the purge gas, the source gases and the purge gas may mix on the surface of the substrate, and the source gases may be diluted by the purge gas. Therefore, a concentration of the first reaction gas may lower when the susceptor or the substrate holder is rotated at high speed, and it may not be possible to cause the first reaction gas to positively adsorb on the surface of the wafer. Further, a concentration of the second reaction gas may lower, oxidation of the first reaction gas may not be sufficiently carried out, a film having a large amount of impurities may be deposited, and as a result, it may not be possible to deposit a thin film having satisfactory quality.

In a configuration of a patent document 3 (international publication No. WO 2009/017322 A1, the same hereinafter), as shown in FIG. 4 of the patent document 3, a first reaction gas is supplied by a source gas showerhead 270a. Then, a second reaction gas is supplied through a showerhead 270b provided at a position facing the source gas showerhead 270a and having the same area as the source gas showerhead 270a. Further, an inactive gas is supplied from a facing zone 270c having a wide area and sandwiched by the showerhead 270a and the showerhead 270b. These gases are ejected from evacuation passages 238a and 238b shown in FIG. 5 of the patent document 3 via plural openings 236a and 236b disposed equally throughout a circumference on a baffle plate that surrounds an outer circumference of a turntable that is rotated and has six wafers W placed thereon shown in FIG. 6 of the patent document 3. As a result of such a configuration being provided, reactions of first and second reaction gases are made to progress in processing spaces having the showerheads 270a and 270b disposed to face one another and having the equal area.

In a configuration of a patent document 4 (U.S. Pat. No. 6,932,871, the same hereinafter), as shown in FIG. 2 of the patent document 4, a process is carried out in such a manner that a turntable 802 on which six substrates are placed is rotated below a showerhead disposed to face the substrate. Further, a space in which the process is carried out is divided to processing spaces having equal areas by curtains 204 of inactive gas A, B, C, E and F.

In a configuration of a patent document 5 (United States patent publication No. 2006/0073276 A1, the same hereinafter), as shown in FIG. 8 of the patent document 5, two different reaction gases are introduced into process areas having sizes of the same areas from two slits 200 and 210 disposed to face one another. The reaction gases are ejected from evacuation areas 220 and 230 surrounding these process areas that have the same areas, in communication with a vacuum evacuation means which is provided above an apparatus.

In a patent document 6 (United States patent publication No. 2008/0193643 A1, the same hereinafter), an art is disclosed in which inner spaces of a vacuum chamber are determined at positions of four partition plates 72, 74, 68 and 70. As a first invention embodiment, an embodiment is shown in which these partition plates pass through a rotation center, and are disposed to face each other linearly. As shown in FIGS. 2 and 4 of the patent document 5 showing the first invention, a first reaction gas 90 passes through gas introducing pipes 112 and 116, and is introduced to the inside of a space 76 obtained from the inside of the vacuum chamber being divided into four. Then, a gas is introduced from a second reaction gas supplying system 92 to a space 80 that is another one of the four divisions disposed to face the space 76 and having the same area. Further, an inactive gas is introduced to spaces that are narrow spaces 82 and 84 sandwiched by the processing spaces disposed to face one another and having the equal areas. Further, as shown in FIG. 3A, the inside of the vacuum chamber is evacuated by a vacuum pump 64 via an evacuation passage 42 provided upward above the rotation center.

On the other hand, according to FIG. 8 showing a second invention embodiment of the specification of the patent document 6, walls dividing a processing space in the inside of a vacuum chamber are moved to uneven positions from those of being divided into the four. As a result, spaces 80a and 76a disposed to face one another have large areas, and spaces 82a and 78a have small areas.

Further, according to FIG. 9 of the patent document 6, an area of a space 80b disposed to face another space is small, and an area of a space 76a is large. Any of these embodiments are embodiments in which the partition plates are moved, and the areas of the spaces are changed. In these configurations, in order that the reaction gases supplied to the plural process spaces are separated and are prevented from mixing, the adjacent spaces enclosed by the partition plates are filled with the inactive gas.

According to paragraphs 0061 through 0064 in a detailed description of a specification corresponding to these figures of the patent document 6, partitions 68b, 70b, 72b and 74b are moved to form the spaces having the areas suitable to the process. However, the following points can be said throughout the patent document 6. That is, (1) the space configuration of the vacuum chamber is such that, the walls are formed by the physical partitions, and the reaction gases and the inactive gas are made to flow into the spaces enclosed by the walls, and the spaces are filled therewith. (2) A method of evacuation is of upward evacuation positioned at the rotation center. (3) There is no technique that is necessary for high-speed rotation to avoid reaction of the reaction gases together, and thus, the art is applicable to a low speed (20 through 30 rpm).

Therefore, even by using the arts of the patent document 3 through the patent document 6, it is not possible to solve the problem to be solved by the present invention shown below. That is, even by the arts of the above-mentioned patent document 3 through the patent document 6, it may not be possible to carry out a satisfactory deposition process by preventing mixture of the first and second reaction gases, and also causing adsorption reaction by the first reaction gas and oxidation reaction by the second reaction gas to progress sufficiently in a case where the rotation speed of the turntable is increased.

### SUMMARY OF THE INVENTION

The present invention provides a film deposition apparatus by which ALD film deposition reaction per one rotation is accelerated and a film thickness per one rotation is large. Further, the present invention provides a film deposition apparatus by which a growing speed of a film thickness can be maintained even when high speed rotation is carried out, a film thickness corresponding to the rotation speed is obtained, and further, it is possible to carry out film deposition having high quality.

The present invention is a film deposition apparatus in which, in a vacuum chamber, a turntable on which plural substrates are placed is rotated, the substrate comes into contact, in sequence, with reaction gases supplied to plural different process areas, and a thin film is deposited on a surface of the substrate.

The film deposition apparatus has the following configuration. That is, a reaction gas supplying portion is provided in the process area to face the proximity of the substrate that is revolving, and supplies the reaction gas toward the substrate. Further, a separation gas supplying portion is provided between the plural process areas, which supplies a separation gas to a separation area provided between the plural process areas, for preventing the different reaction gases from reacting together. Further, in the respective outsides of the plural process areas, an evacuation mechanism is provided by which evacuation ports are provided in areas corresponding to peripheral directions of the turntable, the reaction gases supplied to the process areas and the separation gas supplied to the separation area are introduced to the evacuation ports via the process areas, and are ejected in communication with the evacuation ports. The plural process areas include a first process area in which a process of a first reaction gas adsorbing on the surface of the substrate is carried out. The plural process areas include a second process area that has a larger area than the first process area, in which a process of causing the first reaction gas having adsorbed on the surface of the substrate to react with the second reaction gas and depositing a film on the surface of the substrate is carried out.

### BRIEF DESCRIPTION OF THE DRAWINGS

FIG. 1 shows a sectional view taken along a I-I′ line of FIG. 3 and shows a longitudinal sectional view of a film deposition apparatus in an embodiment of the present invention;

FIG. 2 shows a perspective view showing a general configuration of the inside of the above-mentioned film deposition apparatus;

FIG. 3 shows a cross-sectional plan view of the above-mentioned film deposition apparatus;

FIGS. 4A and 4B show longitudinal sectional views showing process areas and a separation area in the above-mentioned film deposition apparatus;

FIG. 5 shows a longitudinal sectional view showing a part of the above-mentioned film deposition apparatus;

FIG. 6 shows a plan view showing a part of the above-mentioned film deposition apparatus;

FIG. 7 illustrates a manner in which a separation gas or a purge gas flows;

FIG. 8 shows a partial cutaway perspective view of the above-mentioned film deposition apparatus;

FIG. 9 illustrates a manner in which a first reaction gas and a second reaction gas are separated by a separation gas and are ejected;

FIG. 10 shows a cross-sectional plan view showing a film deposition apparatus in another embodiment of the present invention;

FIG. 11 shows a perspective view showing a plasma generating mechanism used in the above-mentioned film deposition apparatus;

FIG. 12 shows a cross-sectional view showing the above-mentioned plasma generating mechanism;

FIG. 13 shows a cross-sectional plan view of a film deposition apparatus in a further other embodiment of the present invention;

FIGS. 14A and 14B show sectional views showing parts of the film deposition apparatus in the further other embodiment of the present invention;

FIGS. 15A and 15B show a perspective view and a plan view showing a nozzle cover used in the above-mentioned film deposition apparatus;

FIGS. 16A and 16B show sectional views illustrating a function of the above-mentioned nozzle cover;

FIG. 17 shows a cross-sectional plan view of a film deposition apparatus in a further other embodiment of the present invention;

FIG. 18 shows a general plan view showing one example of a substrate processing system using a film deposition apparatus according to the present invention; and

FIGS. 19, 20A, 20B, 21A and 21B show characteristic diagrams showing a result of an evaluation experiment carried out for the purpose of confirming advantageous effects of the present invention.

### DETAILED DESCRIPTION OF PREFERRED EMBODIMENTS

According to an embodiment of the present invention, an area of a second process area for carrying out a process of causing a first reaction gas having adsorbed on a surface of a substrate and a second reaction gas to react and depositing a film is set larger than a first process area for carrying out a process of causing the first reaction gas to adsorb on the surface of the substrate. As a result, in comparison to a case where areas in which the first and second reaction gases react are equal (processing areas of both are the same), it is possible to acquire a long processing time period for the film deposition process. Thereby, a film thickness growth per single rotation becomes thicker, it is possible to acquire a high film deposition speed by increasing the rotation speed of a turntable while a deposition film thickness per single rotation is maintained, and also, it is possible to carry out a film deposition process of satisfactory film quality.

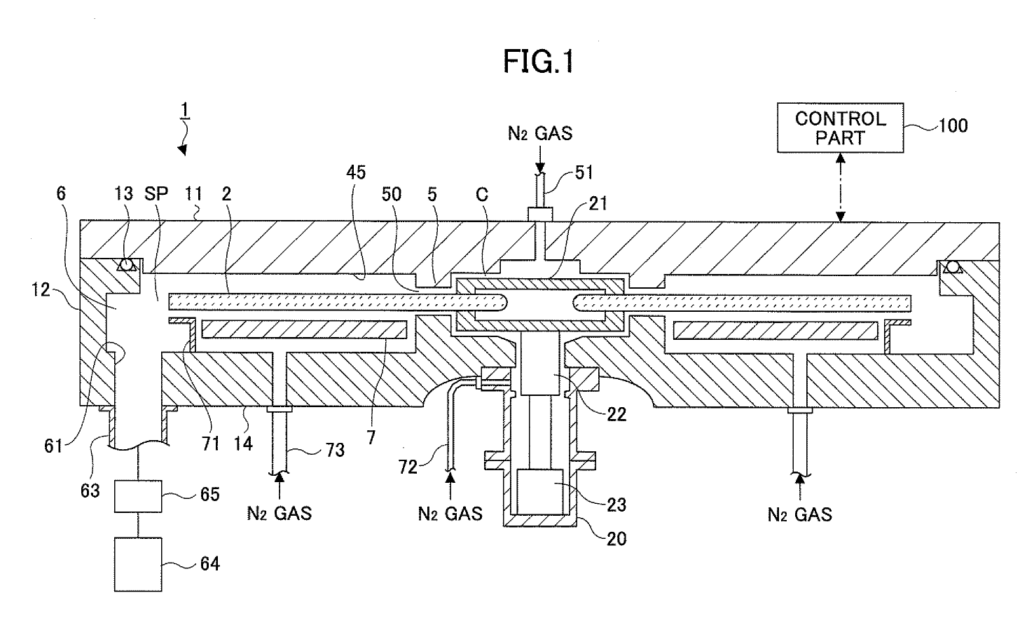

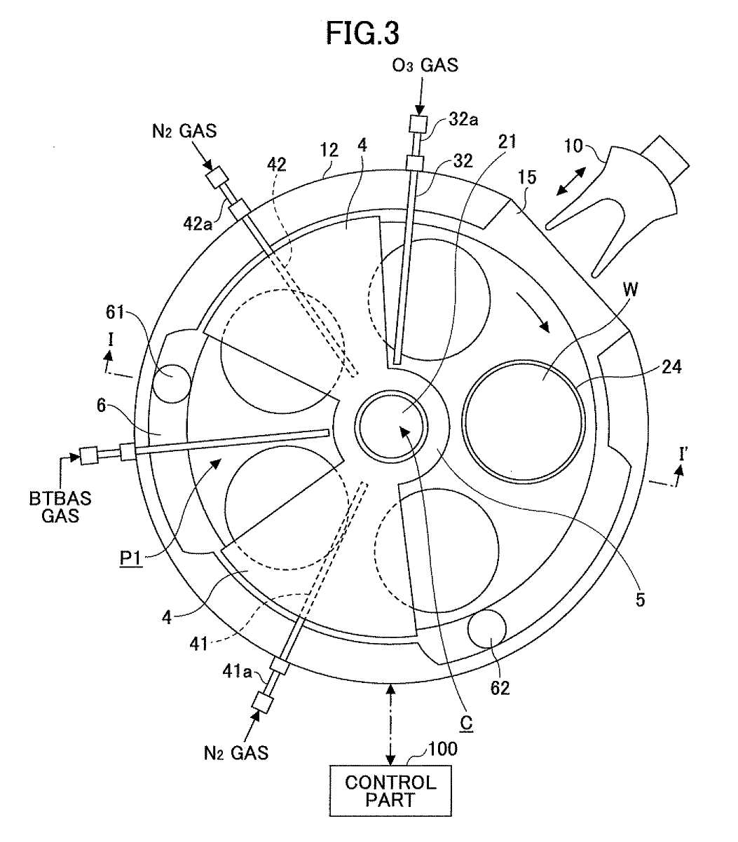

A film deposition apparatus according to an embodiment of the present invention includes a flat vacuum chamber 1 having an approximately circular plan shape as shown in FIG. 1 (sectional view taken along the I-I′ line of FIG. 3). The film deposition apparatus further includes a turntable 2 provided in the vacuum chamber 1 and having a rotation center at a center of the vacuum chamber 1. The vacuum chamber 1 is configured so that a ceiling plate 11 can be separated from a chamber body 12. The ceiling plate 11 is pressed to the chamber body 12 via a sealing member such as an O-ring 13 for example by a reduced pressure condition of the inside, and thereby, an air-tight condition is maintained. When the ceiling plate 11 is to be separated from the chamber body 12, the ceiling plate 11 is lifted by a driving mechanism (not shown).

A center portion of the turntable 2 is fixed to a core portion 21 having a cylindrical shape, and the core portion 21 is fixed to a top end of a rotational shaft 22 extending vertically. The rotational shaft 22 passes through a bottom portion 14 of the vacuum chamber 1, and a bottom end of the rotational shaft 22 is mounted on a driving part 23 that rotates the rotational shaft 22 on a vertical axis, i.e., a clockwise in this example. The rotational shaft 22 and the driving part 23 are held by a cylindrical case body 20 having an open top end. A flange part provided on the top end of the case body 20 is mounted, in an air-tight manner, on a bottom surface of the bottom portion 14 of the vacuum chamber 1, and an air-tight condition between an atmosphere in the inside of the case body 20 and an external atmosphere is maintained.

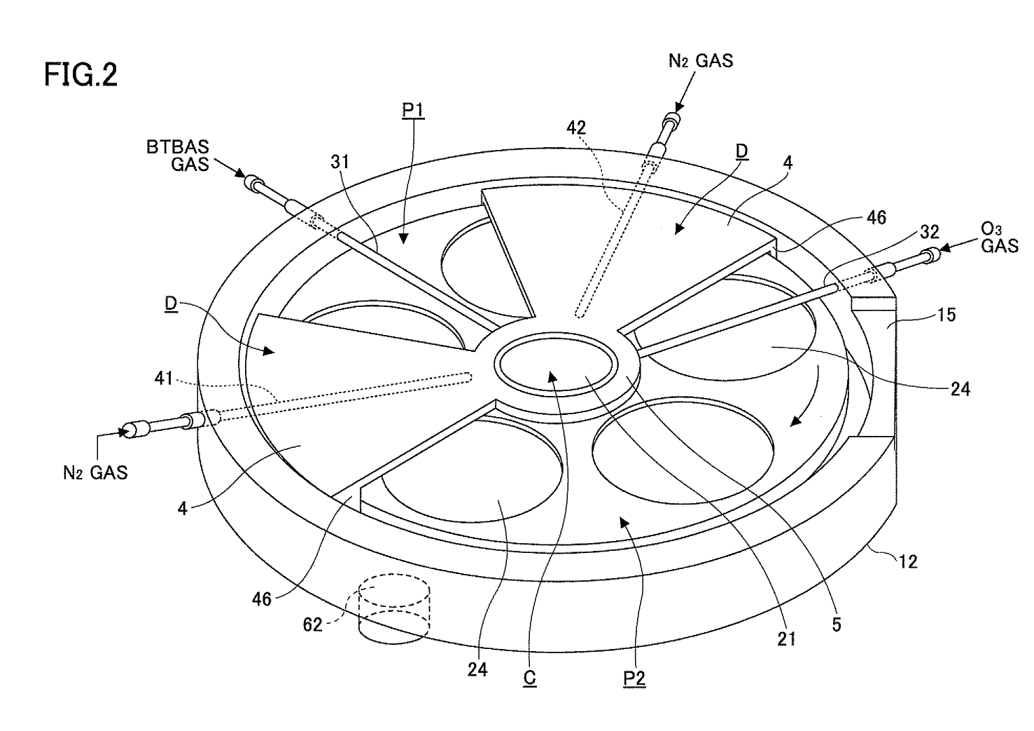

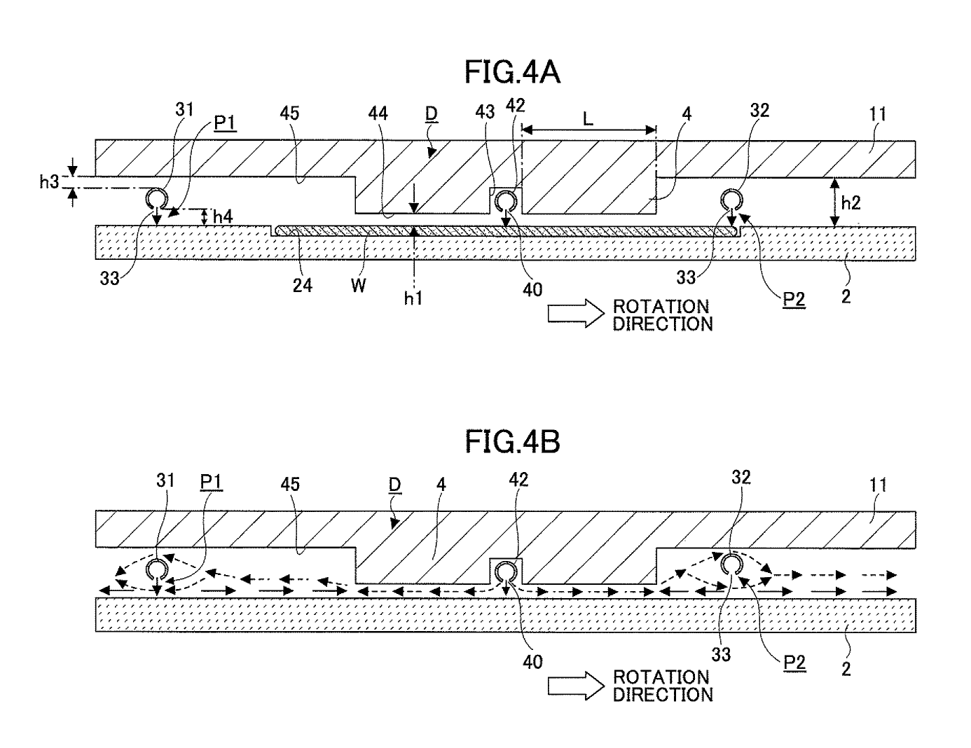

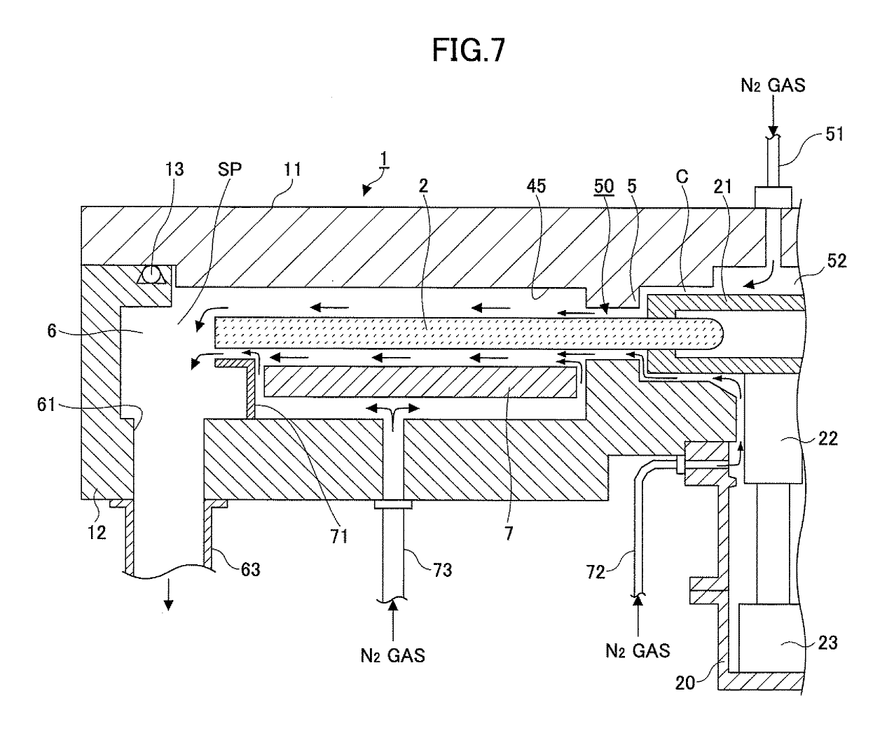

As shown in FIGS. 2 and 3, on a surface part of the turntable 2, circular concave portions 24 for placing plural, for example, five, wafers that are substrates, are provided along a rotation direction (circumferential direction). It is noted that, for the purpose of convenience, the wafer W is shown only in one concave portion 24 in FIG. 3. FIGS. 4A and 4B are extended views showing the turntable 2 being cut along a concentric circle, and also, being extended horizontally, and the concave portion 24 has a diameter that is larger than a diameter of the wafer slightly, for example, by 4 mm as shown in FIG. 4A. Further, a depth of the concave portion 24 is set equal to a thickness of the wafer. Accordingly, when the wafer is caused to fall in the concave portion 24, a surface of the wafer is flush with a surface of the turntable 2 (an area in which no wafer is placed). If a difference in the heights is large between the surface of the wafer and the surface of the turntable 2, gas purge efficiency lowers because of the step part, and a gas staying time differs. As a result, a gas concentration slope appears, and thus, it is preferable to cause the heights to be equal between the surface of the wafer and the surface of the turntable 2 from the viewpoint of achieving film thickness in-plane uniformity. To make the surface of the wafer flush with the surface of the turntable 2 means the surface of the wafer and the surface of the turntable 2 have the same height, or, a difference between the surfaces falls within 5 mm. It is preferable to reduce the difference between the surfaces to zero as much as possible depending on accuracy of finishing or such. On a bottom surface of the concave portion 24, through holes (not shown) are provided through which, for example, three elevation pins 16 (see FIG. 7) pass for supporting a rear side of the wafer and moving the wafer up and down.

The concave portions 24 are provided for the purpose of positioning the wafers and preventing the wafers from being removed because of centrifugal force caused by rotation of the turntable 2. However, the substrate placing area (wafer placing area) is not limited to such a concave portion, and instead, for example, may be plural guide members that guide a circumferential edge of the wafer provided along a circumferential direction of the wafer on the surface of the turntable 2. Alternatively, in a case where a chucking mechanism such as an electrostatic chuck is provided to the turntable 2, and the wafer is attracted thereby to the surface of the turntable 2, an area to which the wafer is placed as a result of being thus attracted is the substrate placing area.

As shown in FIGS. 2 and 3, in the vacuum chamber 1, a first reaction gas nozzle 31, a second reaction gas nozzle 32 and two separation gas nozzles 41 and 42 extend at a position facing each of passing areas of the concave portions 24 on the turntable 2. The first reaction gas nozzle 31, the second reaction nozzle 32 and the two setting gas nozzles 41, 42 extend at mutual intervals in the circumferential direction of the vacuum chamber 1 (the rotation direction of the turntable 2) radially from the center portion. These reaction gas nozzles 31, 32 and the separation gas nozzles 41, 42 are mounted, for example, on a side circumferential wall of the vacuum chamber 1. Further, gas introduction ports 31a, 32a, 41a, 42a, which are base end parts of the reaction nozzles 31, 32 and the separation gas nozzles 41, 42, pass through the side wall. In an example shown, the gas nozzles 31, 32, 41, 42 are introduced into the vacuum chamber 1 from the circumferential wall of the vacuum chamber 1. However, they may be introduced from an annular protrusion 5 described later. In this case, the following configuration may be adopted. That is, an L-shape conduit is provided which opens on an outer circumferential surface of the protrusion portion 5 and on an outer surface of the ceiling plate 11. Then, the gas nozzle 31 (, 32, 41, 42) is connected to one opening of the L—shape conduit in the vacuum chamber 1. Further, the gas introduction ports 31a (, 32a, 41a, 42a) is connected to the other opening of the L-shape conduit in the outside of the vacuum chamber 1.

The reaction gas nozzles 31, 32 are connected respectively to a gas supplying source for a BTBAS (a bis(tertiary-butylamino) silane) gas that is a first reaction gas and a gas supplying source for a O₃ (ozone) gas that is a second reaction gas (both being not shown). Both of the separation gas nozzles 41, 42 are connected to a gas supplying source (not shown) for a N₂ (nitrogen) gas that is a separation gas. In this example, the second reaction gas nozzle 32, the separation gas nozzle 41, the first reaction gas nozzle 31 and the separation gas nozzle 42 are arranged clockwise in the stated order.

The reaction gas nozzles 31, 32 have ejection holes 33 for discharging the reaction gases downward arranged on bottom sides at intervals along longitudinal directions of the nozzles. In this example, a bore diameter of each ejection hole is 0.5 mm, and the ejection holes are arranged along the longitudinal direction of each nozzle at intervals of, for example, 10 mm. The reaction gas nozzles 31, 32 correspond to a first reaction gas supplying portion and a second reaction gas supplying portion, respectively, and areas below them are a first process area P1 for causing the BTBAS gas to adsorb on the wafer and a second process area P2 for causing the O₃ gas to adsorb on the wafer, respectively. Thus, the respective gas nozzles 31, 32, 41, 42 are arranged and directed toward the rotation center of the turntable 2, and form injectors having plural gas blowout openings (ejection holes) arranged linearly.

These reaction gas nozzles 31, 32 are provided apart from the ceiling parts of the respective process areas P1 and P2 above and in the proximity of the turntable 2 and are configured to supply the reaction gases respectively to the wafer W on the turntable 2. The configuration in which the reaction gas nozzles 31, 32 are apart from the ceiling parts of the respective process areas P1, P2 and provided above and in the proximity of the turntable 2 includes the following configuration. That is, what is necessary is that a space for the gases flowing is formed between top surfaces of the reaction gas nozzles 31, 32 and the ceiling parts of the process areas P1, P2. More specifically, a configuration is included in which a distance between the top surfaces of the reaction gas nozzles 31, 32 and the ceiling parts of the process areas P1, P2 is larger than a distance between bottom surfaces of the reaction gas nozzles 31, 32 and the surface of the turntable 2. Other than this, a configuration is included in which the distances of both are approximately equal. Further, a configuration is included in which the distance between the top surfaces of the reaction gas nozzles 31, 32 and the ceiling parts of the process areas P1, 92 is smaller than the distance between the bottom surfaces of the reaction gas nozzles 31, 32 and the surface of the turntable 2.

The separation gas nozzles 41, 42 have ejection holes 40 for discharging the separation gas downward bored at intervals along a longitudinal direction. In this example, a bore diameter of each ejection hole is 0.5 mm, and the ejection holes are arranged along the longitudinal direction of each nozzle at intervals of, for example, 10 mm. These separation gas nozzles 41, 42 act as separation gas supplying portions. The separation gas supplying portions supply the separation gas for preventing the first reaction gas and the second reaction gas from reacting together to a separation area D provided between the first process area 91 and the second process area P2.

On the ceiling plate 11 of the vacuum chamber 11 in the separation areas D, as shown in FIGS. 2 through 4B, convex portions 4 are provided. The convex portions 4 have such a configuration that a circle having a center at the rotation center of the turntable 2 and drawn along the proximity of an inner circumferential wall of the vacuum chamber 1 is divided in a circumferential direction. Further, the convex portions 4 have such a configuration that in a plan view are sectors, and the convex portions 4 protrude downward. The separation gas nozzles 41 and 42 are, in this example, held by groove portions 43 formed to extend in radial directions of the circle of the convex portions 4 at centers in the circumferential direction of the convex portions 4. That is, distances from a central axis of the separation gas nozzle 41 (, 42) to both edges (an upstream edge and a downstream edge in the rotation direction) of the sector that is the convex portion 4 are set to have the same length. It is noted that the groove portion 43 is formed to divide the convex portion 4 into two equal parts in the embodiment. On the other hand, in another embodiment, the groove portion 43 may be formed in such a manner that, from the groove portion 43, an upstream part of the convex portion 4 is wider than a downstream part in the rotation direction of the turntable 2, for example. Accordingly, on both sides in the circumferential direction of the separation gas nozzles 41, 42, flat lower ceiling surfaces 44 (first ceiling surfaces), for example, which are bottom surfaces of the convex portions 4, exist. Ceiling surfaces 45 (second ceiling surfaces) which are higher than the ceiling surfaces 44 exist on both sides in the circumferential direction of the ceiling surfaces 44. One role of the convex portions 4 is to form separating spaces that are narrow spaces for preventing entry of the first reaction gas and the second reaction gas between the convex portions 4 and the turntable 2 to prevent these reaction gases from mixing.

That is, taking the separation gas nozzle 41 as an example, the convex portion 4 prevents entry of the O₃ gas from the upstream side in the rotation direction of the turntable 2. Further, the convex portion 4 prevents entry of the BTBAS gas from the downstream side in the rotation direction of the turntable 2.

“To prevent entry of the gas” will now be described. The N₂ gas that is the separation gas discharged from the separation gas nozzle 41 diffuses between the first ceiling surface 44 and the surface of the turntable 2. In this example, the N₂ gas discharges to spaces below the second ceiling surfaces 45 adjacent to the first ceiling surface 44, and thereby, no gas can enter from adjacent spaces. “No gas can enter” not only means a case where no gas can enter to the space below the convex portion 4 from the adjacent spaces at all, but also means a case where the gas can somewhat enter but a condition in which the O₃ gas and the BTBAS gas entering from both sides do not mix together below the convex portion 4 is ensured. As long as such a function is obtained, a function of separating between an atmosphere of the first process area P1 and an atmosphere of the second process area P1, which is the role of the separation area, D can be played. Accordingly, a degree of narrow of the narrow space is such that a size of the narrow space is set and thus, a pressure difference between the narrow space (the space below the convex portion 4) and the spaces adjacent to the narrow space (the spaces below the second ceiling surfaces 45 in this example) is so small that the function of “no gas can enter” can be ensured. A specific size of the narrow space depends on an area of the convex portion 4 or such. Further, a gas having adsorbed on the wafer can, of course, pass through the separation area D, and, a gas of to prevent entry of the gas means a gas in a gas phase.

In this example, thus, the first process area P1 and the second process area P2 are divided from one another by the separation areas D. Areas below the convex portions 4 having the first ceiling surfaces 44 are the separation areas, and areas having the second ceiling surfaces 45 on both sides in the circumferential direction of the convex portions 4 are the process areas. In this example, the first process area P1 is formed in an area adjacent in a downstream side in the rotation direction of the turntable 2 of the separation gas nozzle 41. The second process area P2 is formed in an area adjacent in an upstream side in the rotation direction of the turntable 2 of the separation gas nozzle 41.

The first process area P1 is an area in which metal is caused to adsorb on the surface of the wafer W, and, in this example, silicon that is the metal is caused to adsorb by the BTBAS gas. The second process area P2 is an area in which chemical reaction of the metal is caused is caused to occur. The chemical reaction includes, for example, an oxidation reaction and nitriding reaction of the metal, and in this example, an oxidation reaction of silicon by the O₃ gas is carried out. It is noted that these process areas P1 and P2 can be said to be diffusion areas in which the reaction gases diffuse.

Further, an area of the second process area P2 is set to be larger than an area of the first process area P1. This is because, as mentioned above, adsorption of the metal (silicon) is carried out in the first process area P1 by the first reaction gas, and, in the second process area P2, the chemical reaction on the metal formed in the first process area by the second reaction gas P1 progresses. There, the first reaction gas and the second reaction gas have different reaction modes, and a reaction speed is higher in the adsorption reaction than the chemical reaction.

A feature of a first reaction gas supplying portion is such that the first reaction gas is discharged toward the surface of the wafer W on the turntable 2, and simultaneously, the first reaction gas supplying portion is an injector that is a gas supplying device having ejection holes arranged linearly.

Further, in the sector-shaped first process area P1 in which the first reaction gas supplying portion is disposed and expands in such a manner that a pivot of the sector is the axis, the first reaction gas adsorbs on the surface of the wafer W immediately when the first reaction gas reaches the surface of the wafer W. Therefore, it is possible that the first process area P1 is a space having a small area. In contrast thereto, the second process is a process supposing an existence of the first reaction gas previously having adsorbed on the surface of the wafer W. As specific embodiments of the second process, an oxidation process, a nitriding process and a High-K film deposition process may be cited. What is common to these reactions is that the second process is a process requiring a time for each reaction. Therefore, it is important that the second reaction gas that has been supplied at a first half in the rotation direction of the turntable 2 in the second process area reaches the entirety of the second process area P2 and the reaction is continued throughout the length of the second process area P2 having the wide area. Thus, in the second process area P2 in which the second reaction gas is supplied and having the area wider than the first process area 21 in which the first reaction gas is supplied, the wafer W passes in the second reaction gas for a long time while the surface reaction is carried out.

It is noted that the more the second process progresses, the more a resulting film thickness increases and thus, the more a film thickness per one rotation increases, and thus, the present invention was reached. Conversely, when the areas of the first and second process areas P1 and P2 are set equal, the wafer W enters the adjacent separation area D along rotation of the turntable 2 in a condition in which the deposition process in the second process area 22 may not have progressed sufficiently, and the second reaction gas having reached the surface of the wafer W is swept away by the separation gas. Therefore, the film deposition and oxidation (nitriding) process does not progress more. That is, while a deposition film thickness per one rotation is thin, film deposition is repeated little by little so as to obtain a film thickness, the same as the film deposition apparatus in the related art.

Thus, according to the present invention, by sufficiently understanding respective roles played by the first and second reaction gases and characteristics thereof contributing the reactions, it is possible to increase a film deposition amount per one rotation by setting a higher-efficiency area ratio for increasing a deposition film thickness. Therefore, a deposition film thickness per one rotation is increased, and the deposition film thickness can be maintained even though the turntable 2 is rotated at high speed such as 120 rpm through 140 rpm. Therefore, it is possible to achieve a film deposition apparatus that is suitable to mass production by which the more the turntable 2 is rotated at high speed, the more the film deposition speed increases. In contrast thereto, according to a minibatch-type rotation-type film deposition apparatus in the related art, the maximum rotation speed may be normally 20 rpm through 30 rpm, and the rotation at higher speed may be difficult.

Further, in order to obtain the advantageous effect of the present invention, the inventors make gaps between the peripheral side of the turntable 2 in the separation areas D in which the separation gas is supplied and the corresponding side wall of the vacuum chamber so small that substantially no gas flows therethrough. Thus, a flow of the separation gas is formed in which the separation gas supplied to the separation areas D flow across the insides of the adjacent process areas in the rotation direction toward evacuation ports provided in the peripheral directions of the turntable, and the separation gas is ejected in a vacuum manner by a vacuum pump that communicates with the evacuation ports.

Further, a configuration is provided such that the separation areas D of the separation gas for preventing the plural different reaction gases from mutually reacting can be maintained even in high-speed rotation. Further, by supplying the separation gas from the rotation center of the turntable 2, so-called curtains of the gas are formed in which the separation gas crosses the rotation center in the rotation-center directions of the separation areas D and crosses the vacuum chamber. Thus, development of a technique in which separating of the plural different reaction gases even at high-speed rotation was successful. Below, also these points will be described.

As mentioned above, the absorption process sufficiently progresses even though the area of the first process area in which adsorption of the first reaction gas is carried out is not so large. On the other hand, a processing time is required for causing chemical reaction to progress sufficiently. Therefore, it is necessary to obtain a processing time by making the area of the second process area P2 to be larger than the first process area P1. Further, if the area of the first process area P1 is too wide, the expensive first reaction gas diffuses in the first process area P1 and an amount of the gas not adsorbing but being ejected may increase, and it may be necessary to increase a supplying amount of the gas. Also from this viewpoint, it is advantageous that the area of the first process area is narrow.

Further, in the first and second process areas P1 and P2, it is preferable to provide the respective reaction gas nozzles 31 and 32 at center portions in the rotation direction or the first half sides of the center portions along the rotation direction (the upstream sides in the rotation direction). This is for the purpose that components of the reaction gas supplied to the wafer W sufficiently adsorb on the wafer W, and the components of the reaction gas having already adsorbed on the wafer W and the reaction gas having newly adsorbed on the wafer W are sufficiently reacted. In this example, the first reaction gas nozzle 31 is provided at an approximately center portion in the rotation direction of the first process area P1 and the second reaction gas nozzle 32 is provided on the upstream side of the rotation direction in the second process area P2.

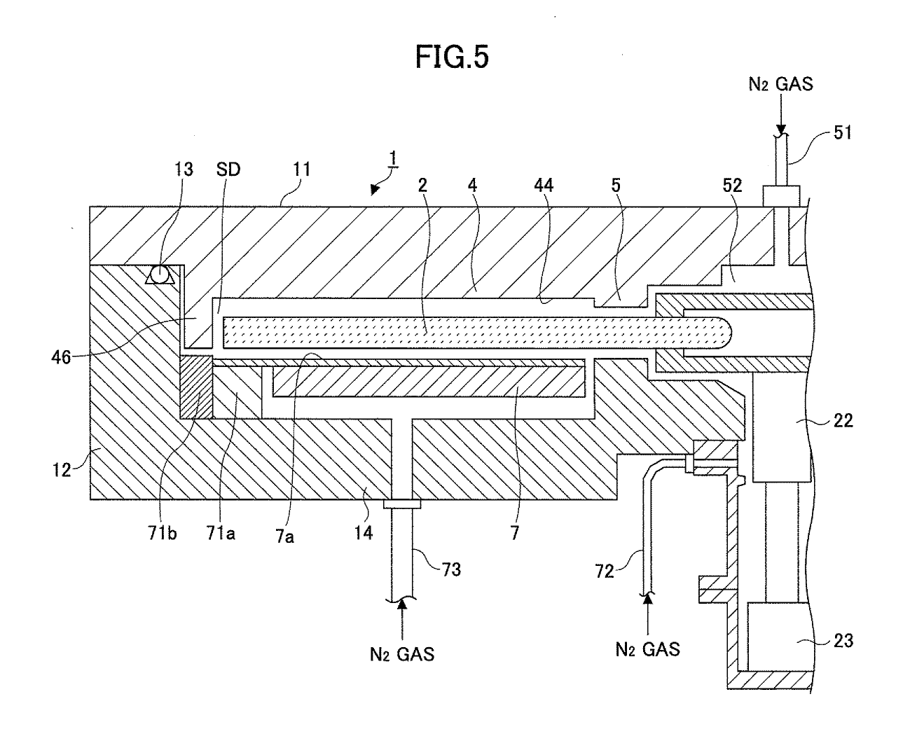

On the other hand, on the bottom surface of the ceiling plate 11, the protrusion portion 5 is provided along the outer circumference of the core portion 21 to face a part of the turntable 2 on the periphery side of the core portion 21. The protrusion portion 5 is formed to continue from parts of the convex portions 4 on the rotation-center side, and a bottom surface of the protrusion portion 5 is formed, as shown in FIG. 5, slightly lower than a bottom surfaces (ceiling surfaces 44) of the convex portions 4. A reason why the bottom surface of the protrusion portion 5 is provided slightly lower than the bottom surface of the convex portion 4 is to ensure a pressure balance at the center portion of the turntable 2, and a driving clearance is small at the center portion in comparison to the periphery side. FIGS. 2 and 3 show configurations obtained from the ceiling plate 11 being horizontally cut at a position lower than the ceiling surface 45 and higher than the separation gas nozzles 41 and 42. It is noted that the protrusion portion 5 and the convex portions 4 are not necessarily an integrated part but may be separated parts.

How to form a configuration of combining the convex portion 4 and the separation gas nozzle 41 (42) is not limited to a configuration in which the groove 43 is formed at a center of the single sector plate that forms the convex portion 4 and the separation gas nozzle 41 (42) is deposed in the groove 43. A configuration may also be used in which two sector plates are used, and the sector plates are fixed in a bolting manner to the bottom surface of the ceiling plate body at positions on both sides of the separation gas nozzle 41 (42), or such.

In a bottom surface of the ceiling plate 11 of the vacuum chamber 1, i.e., a ceiling surface viewed from wafer placing areas (concave portions 24) of the turntable 2, the first ceiling surfaces 44 and the second ceiling surfaces 45 higher than the first ceiling surfaces 44 exist in the circumferential direction as mentioned above. FIG. 1 shows a longitudinal sectional view for areas in which the higher ceiling surfaces 45 are provided, and FIG. 5 shows a longitudinal sectional view for areas in which the lower ceiling surfaces 44 are provided. Peripheral parts of the sector-shaped convex portions 4 (parts on the outer edge side of the vacuum chamber 1) form bent parts 46 which are bent in a L shape to face an outer end surface of the turntable 2, as shown in FIGS. 2 and 5. The sector-shaped convex portions 4 are provided on the side of the ceiling plate 11 and can be removed from a chamber body 12. Therefore, a slight gap exists between outer circumferential surfaces of the bent parts 46 and the chamber body 12. Also the bent parts 46 are provided for the purpose of avoiding the reaction gases from entering from both sides, the same as the convex portions 4. A gap between inner circumferential surfaces of the bent parts 46 and the outer end surface of the turntable 2 is set to be approximately 10 mm in consideration of thermal expansion of the turntable 2. On the other hand, the gap between the outer circumferential surfaces of the bent parts 46 and the chamber body 12 is set to be the same as a height h1 of the ceiling surfaces 44 with respect to the surface of the turntable 2. It is preferable that these are set within an appropriate range for the purpose of ensuring the purpose that mixing of both reaction gases is avoided, in consideration of thermal expansion and so forth. In this example, from an area on the surface of the turntable 2, it can be seen that, the inner circumferential surfaces of the bent parts 46 form the side wall (inner circumferential wall) of the vacuum chamber 1.

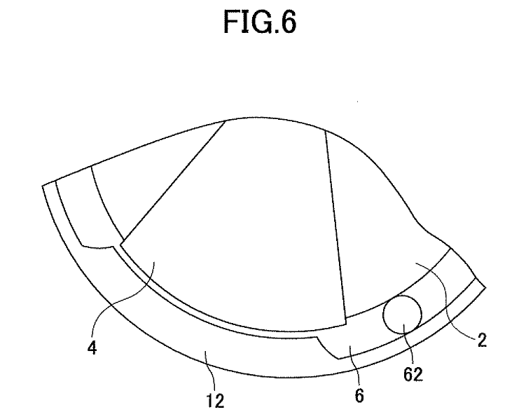

In the separation areas D, an inner circumferential wall of the chamber body 12 is formed closely to the outer circumferential surfaces of the bent parts 46 in a vertical surface as shown in FIG. 5. On the other hand, in the process areas P1 and P2, as shown in FIG. 1, the inner circumferential wall of the chamber body 12 has a longitudinal sectional view of being cut out in a rectangular shape to be hollow outwardly, from a part facing the outer end surface of the turntable 2 through the bottom portion 14, for example. That is, gaps SD between the turntable 2 and the inner circumferential wall of the vacuum chamber in the separation areas D are set narrower than gaps SP between the turntable 2 and the inner circumferential wall of the vacuum chamber in the process areas P1 and P2. It is noted that in the separation areas D, as mentioned above, the inner circumferential surfaces of the bent parts 46 form the inner circumferential wall of the vacuum chamber 1. Therefore, as shown in FIG. 5, the gaps SD correspond to gaps between the circumferential surfaces of the bent parts 46 and the turntable 2. Further, assuming that the above-mentioned hollow parts are referred to as evacuation areas 6, the gaps SP correspond to, as shown in FIGS. 1 and 7, gaps between inner circumferential surfaces of the evacuation areas 6 and the turntable 2. It is noted that the case where the gaps SD in the separation areas D are set narrower than the gaps SP in the process areas P1 and P2 includes a case where, as shown in FIG. 6, parts of the convex portions 4 are inserted into the evacuation areas 6. Further, in this example, in the separation areas D, the inner circumferential surfaces of the bent parts 46 form the inner circumferential wall of the vacuum chamber 1. However, the bent parts 46 are not necessarily required. In a case where no bent parts 46 are provided, gaps between the turntable 2 and the inner circumferential wall of the vacuum chamber 1 in the separation areas D are set narrower than gaps between the turntable 2 and the inner circumferential wall of the vacuum chamber 1 in the process areas P1 and 22.

As shown in FIGS. 1 and 3, on bottoms of the evacuation areas 6, two evacuation ports (a first evacuation port 61 and a second evacuation port 62) are provided, for example. These first and second evacuation ports 61 and 62 are connected to, for example, the vacuum pump 64 that is a vacuum evacuation mechanism, via evacuation pipes 63, respectively. It is noted that, in FIG. 1, 65 denotes a pressure adjustment mechanism which may be provided for each of the evacuation ports 61 and 62 or may be provided in common.

The above-mentioned first evacuation port 61 is provided within an area corresponding to a peripheral direction of the turntable 2 on the outer side of the turntable 2 in the outside of the first process area 21. The first evacuation port 61 is provided, for example, between the first reaction gas nozzle 31 and the separation area D adjacent in the downstream side of the rotation direction of the first reaction gas nozzle 31. The second evacuation port 62 is provided within an area corresponding to a peripheral direction of the turntable 2 on the outer side of the turntable 2 in the outside of the second process area 22. The second evacuation port 62 is provided, for example, between the second reaction gas nozzle 32 and the separation area D adjacent in the downstream side of the rotation direction of the second reaction gas nozzle 32. This is for the purpose that the separating functions of the separation areas D can positively function, and, in a plan view, the evacuation ports 61 and 62 are provided on both sides in the rotation direction of the separation areas D. The first evacuation port 61 is used exclusively to eject the first reaction gas and the second evacuation port 62 is used exclusively to eject the first reaction gas.

It is noted that as shown in FIG. 3, it is preferable that the first and second evacuation ports 61 and 62 are provided on the downstream sides in the rotation direction in the process areas, respectively. The second reaction gas nozzle 32 is provided on the upstream side in the rotation direction of the turntable 2 in the second process area P2. As a result, the reaction gas supplied by the reaction gas nozzle 32 passes in the process area P2 from the upstream side through the downstream side in the rotation direction of the turntable 2. Thus, the reaction gas reaches all over the second process area P2. Thereby, it is possible that when the wafer W passes through the second process area P2 having the larger area, the gas is caused to come into contact with the surface of the wafer W sufficiently and chemical reaction is caused to progress.

It is noted that the first process area P1 is narrower than the second process area P2. Therefore, even though the first reaction gas nozzle 31 is provided at the approximate center in the rotation direction of the turntable 2 in the process area P1 as in the present embodiment, the reaction gas can be caused to reach all over the process area P1 sufficiently, and adsorption reaction for the metal layer can be caused to sufficiently progress. It is noted that also the first reaction gas nozzle 31 may be provided on the upstream side in the rotation direction of the turntable 2.

The number of the evacuation ports is not limited to the two. For example, one more evacuation port may be provided between the separation area D that includes the separation gas nozzle 42 and the second reaction gas nozzle 32 adjacent to this separation area D in the downstream side in the rotation direction, and thus, the number of the evacuation ports may be three, or may be equal to or more than four. In this example, evacuation is carried out from a gap between the inner circumferential wall of the vacuum chamber 1 and the circumferential edge of the turntable 2, as a result of the evacuation ports 61 and 62 being provided at positions lower than the turntable 2. However, the evacuation ports 61 and 62 are not limited to be provided on the bottom of the vacuum chamber 1, and may be provided on the side wall of the vacuum chamber 1. Further, in the case where the evacuation ports 61 and 62 are provided on the side wall of the vacuum chamber 1, the evacuation ports 61 and 62 may be provided at positions higher than the turntable 2. By thus providing the evacuation ports 61 and 62, the gases on the turntable 2 flow toward the outside of the turntable 2, and therefore, it is advantageous from a viewpoint that particles are prevented from being raised in comparison to a case where evacuation is carried out from the ceiling surface that faces the turntable 2.

A heater unit 7 that is a heating mechanism is provided as shown in FIGS. 1 and 5 in a space between the turntable 2 and the bottom portion 14 of the vacuum chamber 1. The heater unit 7 heats the wafers on the turntable 2 through the turntable 2 to a temperature determined by a process recipe. Below the turntable 2 in the proximity of the circumferential edge of the turntable 2, a cover member 71 is provided to surround the heater unit 7 throughout the circumference of the heater unit 7. The cover unit 71 is provided to divide an atmosphere from a space above the turntable 2 through the evacuation areas 6 and an atmosphere in which the heater unit 7 is placed. As shown in FIG. 5, in the separation areas D, the cover member 71 is formed by block members 71a and 71b. Thus, in the separation areas D, a gap between top surfaces of the block members 71a and 71b and the bottom surface of the turntable 2 is made smaller, and thus, external entry of the gases into the lower side of the turntable 2 is inhibited. Further, it is more preferable to thus provide the block part 71b below the bent part 46, because it is possible to further inhibit entry of the separation gas to the lower side of the turntable 2. It is noted that, as shown in FIG. 5, a protection plate 7a that holds the heater unit 7 may be placed throughout a top surface of the block member 71a and a top surface of the heater unit 7. Thereby, even if the BTBAS gas and/or O₃ gas flow in the space in which the heater unit 7 is provided, it is possible to protect the heater unit 7. The protection plate 7a may be preferably made from, for example, quartz. It is noted that, in the other figures, the protection plate 7a is omitted.

A part of the bottom surface 14 to the rotation center from a space in which the heater unit 7 is placed to approach the proximity of the center portion of the bottom surface of the turntable, the core portion 21, and a narrow space is formed therebetween. Further, also in a through hole for the rotational shaft 22 that passes through the bottom portion 14, a gap between an inner circumferential surface of the through hole and the rotational shaft 22 is narrow, and these narrow spaces communicate with the inside of the case body 20. In the base body 20, a purge gas supplying pipe 72 for supplying N₂ gas that is purge gas to the narrow space for purging is provided. Further, on the bottom portion 14 of the vacuum chamber 1, purge gas supplying pipes 73 for purging the space in which the heater unit 7 is placed are provided at plural parts in a circumferential direction at positions on the lower side of the heater unit 7.

By thus providing the purge gas supplying pipes 72 and 73, as shown in FIG. 7 in which arrows show flows of the purge gas, a space from the inside of the case body 20 through the space in which the heater unit 7 is placed are purge by the N₂ gas. The purge gas is ejected to the evacuation ports 61 and 62 through the evacuation areas 6 from a gap between the turntable 2 and the cover member 71. Thereby, the BTBAS gas and the O₃ gas are prevented from flowing to one to the other of the first process area P1 and the second process area P2 via the lower side of the turntable 2. Thus, the purge gas also acts as separation gas.

Further, to the center portion of the ceiling plate 11 of the vacuum chamber 1, a separation gas supplying pipe 51 is connected, which supplies N₂ gas that is separation gas to a space 52 between the ceiling plate 11 and the core portion 21. The separation gas supplied to the space 52 is discharged toward the circumferential edge of the turntable 2 along the surface of the turntable 2 on the side of the wafer placing areas through a narrow gap 50 between the protrusion portion 5 and the turntable 2. The space surrounded by the protrusion portion 5 is filled with the separation gas, and therefore, the reaction gas (the BTBAS gas or the O₃ gas) is prevented from mixing between the first process area P1 and the second process area P2 through the center portion of the turntable 2. That is, for the purpose of separating the atmospheres of the first process area P1 and the second process area P2, the film deposition apparatus is divided by the rotation center portion of the turntable 2 and the vacuum chamber 1. Thus, it can be said that a center portion area C is provided in which purging is carried out by using the separation gas and a ejection hole is provided along the rotation direction which discharges the separation gas to the surface of the turntable 2. It is noted that this ejection hole corresponds to the narrow gap 50 between the protrusion portion 5 and the turntable 2. The center portion area C corresponds to a rotation-center-supplying separation gas supplying portion for supplying the separation gas to the inside of the vacuum chamber from the rotation center of the turntable 2.

Further, as depicted in FIGS. 2, 3 and 8, on the side wall of the vacuum chamber 1, a transfer opening 15 is provided to face the second process area P2 to be used for transferring the wafer W that is the substrate between an external transfer arm 10 and the turntable 2. The transfer opening 15 is opened and closed by means of a gate valve not shown provided in a transfer path. Further, the wafer W is transferred between the concave portion 24 that is the wafer placing area on the turntable 2 at a position facing the transfer opening 15 and the transfer arm 10. Therefore, elevation pins and an elevation mechanism (both not shown) for transferring the wafer W are provided for passing through the concave portion 24 and lifting the wafer W from the reverse side at a part corresponding to the transferring position, on the lower side of the turntable 2.

Further, a control part 100 made of a computer is provided in the film deposition apparatus in the present embodiment for controlling operations of the entire apparatus, and a program is stored in a memory of the control part 100 for operating the apparatus. In the program, a group of steps are incorporated for carrying out operations of the apparatus described below, and the program is installed in the control part 100 from a recording medium such as a hard disk, a compact disc, a magneto-optical disk, a memory card, a flexible disk or such.

One example of sizes of respective parts of the film deposition apparatus will now be described for a case as an example where the wafer W having a diameter of 300 mm is used as the substrate to be processed, BTBAS gas is used as the first reaction gas, and O₃ gas is used as the second reaction gas. Further, the rotation speed of the turntable 2 is set on the order of, for example, 1 rpm through 500 rpm. For example, a diameter of the turntable 2 is 960 mm. Further, the convex portion 4 has a length in the circumferential direction (a length of an arc of a concentric circle of the turntable 2) of, for example, 146 mm at a part that is a boundary between the convex portion 4 and the protrusion portion 5 away from the rotation center by 140 mm. A length in the circumferential direction of the convex portion 4 at an outermost part of the wafer placing areas (concave portions 24) is, for example, 502 mm. It is noted that as shown in FIG. 4A, at the outermost part, a length L in the circumferential direction of the convex portion 4 positioned at each of left and right sides from the both sides of the separation gas nozzle (42) is 246 mm.

Further, sizes of the first process area P1 and the second process area P2 are adjusted from an arrangement of the convex portions 4. For example, as to the first process area P1, a length of a circumferential direction (a length of an arc of a concentric circle of the turntable 2) is, for example, 146 mm, at a position that is a boundary of the protrusion portion 5 away from the rotation center by 140 mm. A length in the circumferential direction of the first process area P1 at an outermost part of the wafer placing areas (concave portions 24) is, for example, 502 mm. A length of a circumferential direction (a length of an arc of a concentric circle of the turntable 2) of the second process area P2 is, for example, 438 mm, at a position that is a boundary of the protrusion portion 5 away from the rotation center by 140 mm. A length in the circumferential direction of the second process area P2 at an outermost part of the wafer placing areas (concave portions 24) is, for example, 1506 mm.

Further, as shown in FIG. 4A, the height h1 of the bottom surface of the convex portions 4, i.e., the ceiling surfaces 44, from the surface of the turntable 2 may be, for example, 0.5 mm through 10 mm, and preferably, approximately 4 mm. The narrower the gaps SD in the separation areas D between the turntable 2 and the inner circumferential surface of the vacuum chamber is, the more it is preferable. However, in consideration of clearance of rotation of the turntable 2 and thermal expansion occurring when the turntable 2 is heated, the gap SD may be, for example, 0.5 mm through 20 mm, and preferably, approximately 10 mm.

Further, as shown in FIG. 4A, the height h2 of the ceiling surfaces 45 of the process areas P1, P2 from the surface of the turntable 2 is, for example, 15 mm through 100 mm, and for example, 32 mm. Further, the reaction gas nozzles 31, 32 in the process areas 21, P2 are apart from the ceiling surfaces 45 of the process areas 21, 22, respectively, and are provided above and in the proximity of the turntable 2. There, a height h3 of the top surfaces of the reaction gas nozzles 31, 32 from the ceiling surfaces 45 is, for example, 10 mm through 70 mm. A height h4 of the bottom surfaces of the reaction gas nozzles 31, 32 from the turntable 2 in the process areas 21, P2 is, for example, 0.2 mm through 10 mm. For example, extending ends of the reaction gas nozzles 31, 32 are positioned in the proximity of the protrusion portion 5, and the ejection holes 33 are provided on the reaction gas nozzles 31, 32 such that the reaction gases are discharged to the entirety in the radial directions of the process areas 21, 22.

Actually, depending on process conditions such as kinds and flow rates of the reaction gases, a rotation speed and an operation range thereof of the turntable 2, and so forth, sizes of the first process area P1 and the second process area P2 and sizes of the separation areas D for ensuring a sufficient separating function vary. Therefore, according to the process conditions, the following numerical values are set, for example, based on experiments or such. The numerical values to set include sizes of the convex portions 4, locations of the convex portions 4 for determining the first process area P1 and the second process area 22, the height h1 of the bottom surfaces of the convex portions 4 (first ceiling surfaces 44) from the turntable 2, the height h2 of the surface of the turntable 2 from the second ceiling surfaces 45 in the process areas P1, P2, the height h3 of the top surfaces of the reaction gas nozzles 31, 32 from the second ceiling surfaces 45, the height h4 of the bottom surfaces of the reaction gas nozzles 31, 32 from the turntable 2, and the gap SD between the turntable 2 and the inner circumferential wall of the vacuum chamber in the separation areas D.

Further, the height h2 of the surface of the turntable 2 from the second ceiling surface 45 in the second process area P2 may be larger than the height h2 of the surface of the turntable 2 from the second ceiling surface 45 in the first process area P1. Further, for the height h3 of the top surfaces of the reaction gas nozzles 31, 32 from the second ceiling surfaces 45 and the height h4 of the bottom surfaces of the reaction gas nozzles 31, 32 from the turntable 2, different heights may be set between the first process area 21 and the second process area P2.

It is noted that as the separation gas, not only N₂ gas but also inactive gas such as Ar gas may be used. As the separation gas, not only inactive gas but also hydrogen gas or such may be used. A kind of a gas is not particularly limited as long as the gas does not influence the film deposition process.

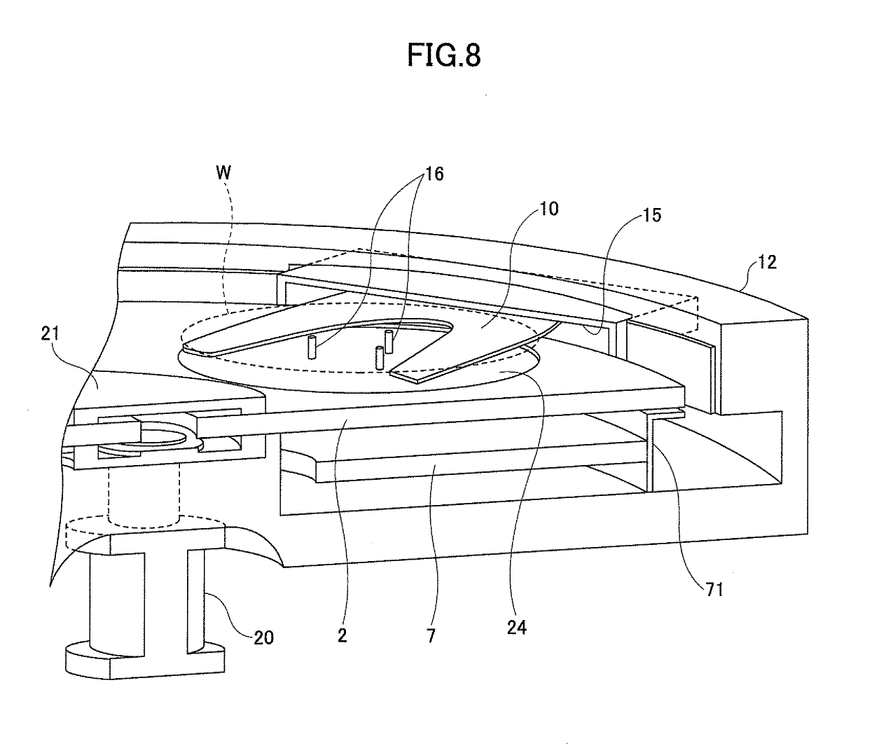

Next, functions of the above-described embodiment will be described. First, the gate valve not shown is opened, and a wafer is transferred from the outside by the transfer arm 10 through the transfer opening 15 to the concave portion 24 of the turntable 2. The transferring is carried out as a result of the elevation pins 16 being lifted and lowered from the bottom side of the vacuum chamber through the through holes of the bottom surface of the concave portion 24, as shown in FIG. 8, when the concave portion 24 stops at a position at which the concave portion 24 faces the transfer opening 15. Such transferring of the wafer W is carried out while the turntable 2 is rotated intermittently, and the wafers W are placed in the five concave portions 24 respectively. Next, the inside of the vacuum changer 1 is evacuated to a previously set pressure by the vacuum pump 64, and also, the wafers W are heated by the heater unit 7 while the turntable 2 is rotated clockwise. In detail, the turntable 2 is previously heated by the heater unit 7 to, for example, 300° C., and the wafers W are heated as a result of the wafers W being placed on the turntable 2. After it is confirmed that the temperatures of the wafers W become the set temperature by a temperature sensor not shown, BTBAS gas and O₃ gas are discharged by the first reaction gas nozzle 31 and the second reaction gas nozzle 32, and also, N₂ gas that is the separation gas is discharged by the separation gas nozzles 41, 42.

Because of rotation of the turntable 2, the wafer W passes through the first process area P1 in which the first reaction gas nozzle 31 is provided and the second process area P2 in which the second reaction gas nozzle 32 is provided, alternately. Thereby, a molecular layer of silicon is produced as a result of the BTBAS gas adsorbing, then the silicon layer is oxidized as a result of the O₃ gas adsorbing, and thus, one or plural molecular layers of silicon oxide is produced. Thus, molecular layers of silicon oxide are laminated in sequence, and a silicon oxide film having a predetermined film thickness is deposited.

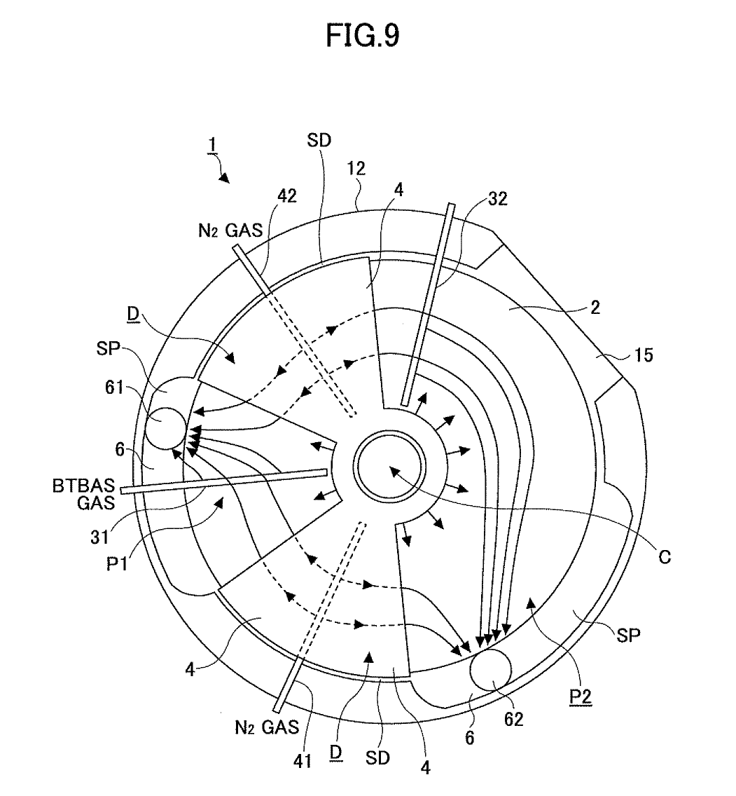

At this time, N₂ gas that is the separation gas is supplied by the separation gas supplying pipe 51, and thereby, the N₂ gas is discharged along the surface of the turntable 2 from the center portion area C, i.e., from between the protrusion portion 5 and the center portion of the turntable 2. In this example, in the inner circumferential wall of the chamber body 12 along spaces below the second ceiling surfaces 45 in which the reaction gas nozzles 31, 32 are disposed, the inner circumferential wall is cut out and wide spaces are formed, and the evacuation ports 61, 62 are positioned at lower parts of the wide spaces. As a result, pressures in the spaces below the second ceiling surfaces 45 become lower than respective pressures in narrow spaces below the first ceiling surfaces 44 and the center portion area C. FIG. 9 diagrammatically shows a manner of flows of the gases when the gases are discharged from the respective parts.

In the first process area P1, the BTBAS gas discharged downward from the first reaction gas nozzle 31 comes into contact with the surface of the turntable 2 (both the surface of the wafer W and the surface other than the wafer placing areas) and flows toward the first evacuation port 61 along the surface of the turntable 2. At this time, the BTBAS gas is, together with the N₂ gas discharged from the sector-shaped convex portions 4 adjacent in the upstream side and downstream side of the rotation direction, and the N₂ gas discharged from the center portion area C, ejected to the first evacuation port 61 through the evacuation area 6 from the gap SP between the circumferential edge of the turntable 2 and the inner circumferential wall of the vacuum chamber 1. Thus, the first reaction gas and the N₂ gas supplied to the first process area P1 are ejected through the first evacuation port 61 through the first process area P1.

Further, the BTBAS gas discharged downward from the first reaction gas nozzle 31, coming into contact with the surface of the turntable 2 and flowing toward the downstream side of the rotation direction along the surface of the turntable 2 is about to flow to the evacuation opening 61 because of the flow of the N₂ gas discharged from the center portion area C and a suction function of the evacuation opening 61. A part of the BTBAS gas is about to flow to the separation area D adjacent in the downstream side and is about to flow into the lower side of the sector-shaped convex portion 4. However, the height and the length in the circumferential direction of the ceiling surface 44 of the convex portion 4 are set to have dimensions such that entry of the gas to the lower side of the ceiling surface 44 can be avoided, in process parameters for a case of operation including flow rates of the respective gases. Therefore, as shown in FIG. 4B, the BTBAS gas can hardly flow into the lower side of the sector-shaped convex portion 4 or cannot reach the vicinity of the separation gas nozzle 42 even when the BTBAS gas can a little flow into the lower side of the sector-shaped convex portion 4. The BTBAS is forced to flow back to the upstream side in the rotation direction, i.e., to the side of the first process area P1 by the N₂ gas discharged from the separation gas nozzle 42. Then, together with the N₂ gas discharged from the center portion area C, the BTBAS gas is ejected to the evacuation port 61 through the evacuation area 6 from the gap SP between the circumferential edge of the turntable 2 and the inner circumferential wall of the vacuum chamber 1. Thus, the separation gas discharged from the center portion area C is ejected from the first evacuation port 61 through the first process area P1.

Further, in the second process area P2, the O₃ gas discharged downward from the second reaction gas nozzle 32 flows toward the second evacuation port 62 along the surface of the turntable 2. At this time, the O₃ gas flows into the evacuation area 6 between the circumferential edge of the turntable 2 and the inner circumferential wall of the vacuum chamber 1 and is ejected by the second evacuation port 62, together with the N₂ gas discharged from the convex portions 4 adjacent on the upstream side and the downstream side in the rotation direction and the N₂ gas discharged from the center portion area C. Thus, the second reaction gas and the N₂ gas supplied to the second process area P2 are ejected through the second evacuation port 62 through the second process area P2.

Also in the second process area P2, the O₃ gas can hardly flow to the lower side of the sector-shaped convex portion 4 or, cannot flow into the vicinity of the separation gas nozzle 41 even when the O₃ gas can flow into the lower side of the convex portion 4 a little. The O₃ gas is forced by the N₂ gas discharged from the separation gas nozzle 41 to flow back to the upstream side in the rotation direction, i.e., to the side of the second process area P2. Then, together with the N₂ gas discharged from the center portion area C, the O₃ gas is ejected by the evacuation port 62 through the evacuation area 6 from the gap between the circumferential edge of the turntable 2 and the inner circumferential wall of the vacuum chamber 1. Thus, the separation gas discharged from the center portion area C is ejected from the second evacuation port 62 through the second process area P2.

Thus, in the respective separation areas D, entry of the BTBAS gas or the O₃ gas that is the reaction gas flowing through the atmosphere is avoided. On the other hand, gas molecules having adsorbed on the wafer pass through the separation areas, i.e., the lower side of the low ceiling surfaces 44 provided by the sector-shaped convex portions 4, and contribute to film deposition. Further, the BTBAS gas of the first process area P1 (the O₃ gas of the second process area P2) is about to flow to the center portion area C. However, as shown in FIGS. 7 and 9, the separation gas is discharged from the center portion area C toward the circumferential edge of the turntable 2. Therefore, entry of the BTBAS gas of the first process area P1 (the O₃ gas of the second process area P2) is avoided by the separation gas, or, the BTBAS gas of the first process area P1 (the O₃ gas of the second process area P2) is forced to flow back even when entering a little. Accordingly, the BTBAS gas of the first process area P1 (the O₃ gas of the second process area P2) is prevented from flowing into the second process area P2 (the first process area P1) through the center portion area C.

Further, in the separation areas D, the peripheral edges of the sector-shaped convex portions 4 are bent downward, the gaps SD between the bent parts 46 and the outer circumferential surface of the turntable 2 become narrow as mentioned above, and passage of gas is substantially avoided. Therefore, the BTBAS gas of the first process area P1 (the O₃ gas of the second process area P2) is also prevented from flowing into the second process area P2 (the first process area P1) through the outside of the turntable 2. Therefore, the atmospheres of the first process area P1 and the atmosphere of the second process area P2 are completely separated by the two separation areas D, and the BTBAS gas is ejected to the first evacuation port 61 and the O₃ gas is ejected to the second evacuation port 62. As a result, both reaction gases, i.e., the BTBAS gas and the O₃ gas in this example, do not mix together in the atmosphere and also on the wafers. It is noted that, in this example, the lower side of the turntable 2 is purged by the N₂ gas. Therefore, there is no possibility that the gas flowing into the evacuation area 6 then passes through the lower side of the turntable 2, and, for example, the BTBAS gas flows into the area in which the O₃ gas is supplied.

Further, the first and second reaction gas nozzles 31, 32 are provided in the proximity of the substrates apart from the ceilings of the respective process areas P1, P2. Therefore, the N₂ gas discharged from the separation gas nozzles 41, 42 is, as shown in FIG. 4B, flows through between the top parts of the reaction gas nozzles 31, 32 and the ceiling surfaces 45 of the respective process areas P1, P2, and through the lower side of the reaction gas nozzles 31, 32. At this time, the reaction gases are discharged from the reaction gas nozzles 31, 32, respectively. Therefore, a pressure is lower on the upper side than on the lower side of the reaction gas nozzles 31, 32. Thereby, the N₂ gas is easier to flow into a space between the top parts of the reaction gas nozzles 31, 32 and the respective ceiling surfaces 45 of the process areas P1, P2, having the lower pressure. Thus, although the N₂ gas flows to the side of the process areas P1, P2, the N₂ gas is not easy to flow into the lower side of the reaction gas nozzles 31, 32. Therefore, the reaction gases discharged by the reaction gas nozzles 31, 32 are supplied to the surfaces of the wafers W without being so diluted by the N₂ gas. After the film deposition process is thus finished, each wafer is transferred out by the transfer arm 10 one by one in an operation reverse to the operation by which each wafer has been transferred in.

One example of the process parameters will now be described. The rotation speed of the turntable 2 is, for example, 1 rpm through 500 rpm in a case where the wafer W having a diameter of 300 mm is used as a to-be-processed substrate, and a processing pressure is, for example, 1067 Pa (8 Torr). A temperature to which the wafer W is heated is, for example, 350° C. Flow rates of the BTBAS gas and the O₃ gas are, for example, 100 sccm and 10000 sccm, respectively. A flow rate of the N₂ gas supplied by the separation gas nozzles 41, 42 is, for example, 20000 sccm. A flow rate of the N₂ gas supplied by the separation gas supplying pipe 51 at the center portion of the vacuum chamber 1 is, for example, 5000 sccm. Further, the number of cycles of supplying the reaction gases to one wafer, i.e., the number of times of the wafer passes through each of the process areas P1, P2, varies depending on a target film thickness, and is many times, for example, 600 times.

By the above-described embodiment, the plural wafers W are placed in the rotation direction on the turntable 2, the turntable 2 is rotated, the wafers W pass through the first process area P1 and the second process area P2 in sequence, and thus, so-called ALD (or MLD) is carried out. Therefore, it is possible to carry out film deposition with high throughput. Further, the separation areas D are provided between the first process area P1 and the second process area P2 in the rotation direction, and the separation gas is discharged toward the process areas P1, P2 from the separation areas D. In the first process area P1, the first reaction gas and the separation gas are together ejected from the evacuation port 61 through the gap SP between the circumferential edge of the turntable 2 and the inner circumferential wall of the vacuum chamber. In the second process area P2, the second reaction gas and the separation gas are together ejected from the evacuation port 62 through the gap SP between the circumferential edge of the turntable 2 and the inner circumferential wall of the vacuum chamber. Thereby, it is possible to prevent both reaction gases from mixing, and as a result, to carry out satisfactory film deposition. Further, there is no reaction product on the turntable 2, or generation of reaction product on the turntable 2 is almost prevented, and generation of particles is prevented. It is noted that the present invention is also applied to a case where the single wafer W is placed on the turntable 2.

Further, the second process area P2 in which the process of causing silicon having adsorbed on the surface of the wafer W to carry out an oxidation reaction is carried out is set to have an area larger than the first process area P1 in which a process of causing the silicon to adsorb on the surface of the wafer W is carried out. Therefore, it is possible to ensure a longer process time of the oxidation reaction of the silicon that requires a time longer than the adsorption reaction of the silicon. Thereby, even when the rotation speed of the turntable 2 is increased, it is possible cause the oxidation reaction of the silicon to progress sufficiently. Further, it is possible to produce a thin film having a small amount of impurities and having satisfactory film quality, and to carry out satisfactory film deposition. Further, since BTBAS gas has high adsorbability for the wafer W, the BTBAS gas immediately adsorbs on the surface of the wafer W as a result of coming into contact with the wafer W, even when the area of the first process area P1 is made smaller. Therefore, if the process area P1 is made larger than is necessary, merely an amount of the BTBAS gas which does not contribute to the reaction and is ejected may increase, and thus, making the area of the first process area P1 smaller is advantageous also from a viewpoint of saving a supplying amount of the BTBAS gas.

Further, in the above-described embodiment, the separation areas D are provided as a result of the convex portions 4 being provided. Therefore, the first process area P1 and the second process area P2 can be divided, and thus, it is possible to further improve the effect of separating the first reaction gas and the second reaction gas.

Further, the gaps SD between the turntable 2 and the inner circumferential wall of the vacuum chamber 1 in the separation areas D are set narrower than the gaps SP between the turntable 2 and the inner circumferential wall of the vacuum chamber 1 in the process areas P1, P2. Further, the evacuation ports 61, 62 are provided in the process areas P1, P2. Thereby, the gaps SP have pressures lower than the gaps SD. Thereby, the greater part of the separation gas supplied from the separation areas D flows toward the process areas P1, P2, and the remaining small amount of the separation gas flows toward the gap SD. The greater part of the separation gas means equal to or more than 90% of the separation gas supplied by the separation gas nozzles 41, 42. Thereby, the separation gas from the separation areas D flows substantially toward the process areas P1, P2 located on both sides of the separation areas D, and hardly flows toward the outside of the turntable 2. As a result, the function of separating the first and second reaction gases by means of the separation areas D is improved.

Further, the transfer opening 15 for the wafers W with which the wafers W are transferred in and transferred out of the vacuum chamber 1 is provided to face the second process area P2. As a result, it is possible to transfer to the outside of the vacuum chamber 1 the wafer W on which the metal oxidation process has been positively carried out.

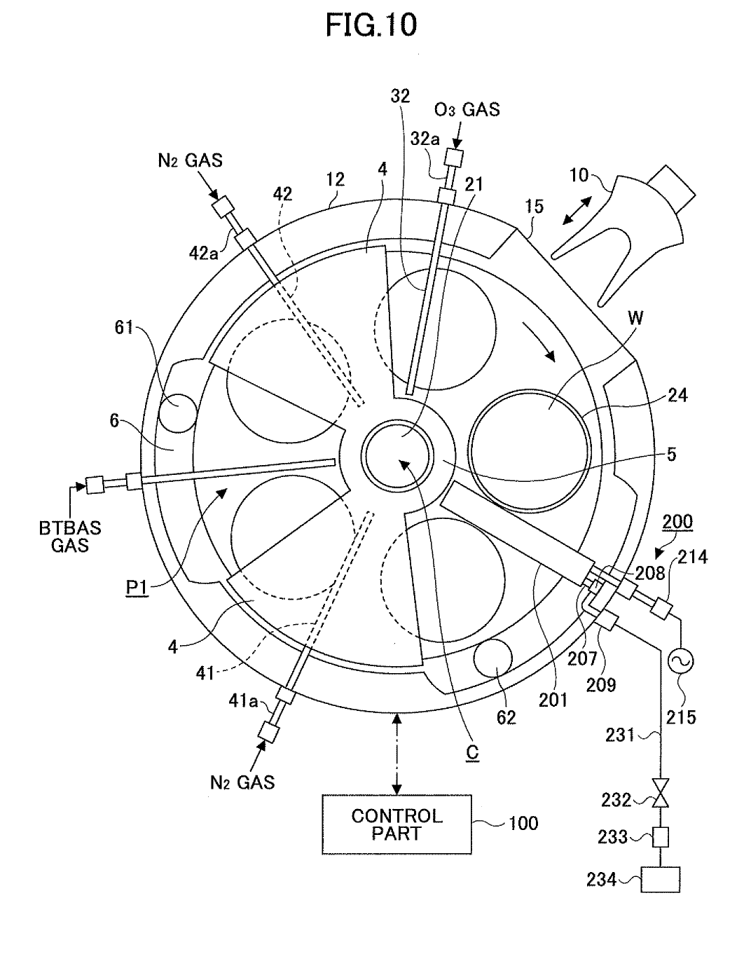

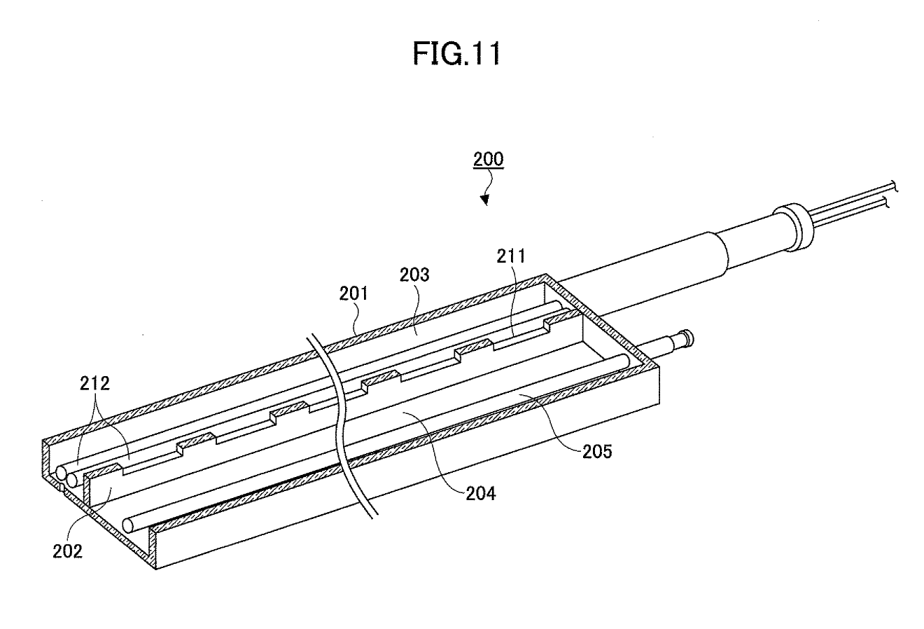

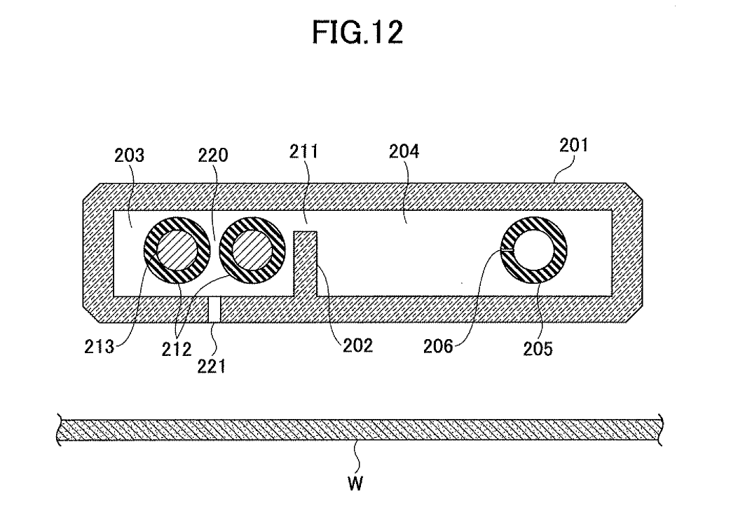

Next, a second embodiment of the present invention will be described based on FIGS. 10 through 13. This embodiment is such that a plasma generation mechanism 200 is provided which carries out surface modification by using plasma of a wafer W on which film deposition has been carried out in the second process area P2, at a second half part (the downstream side) along the rotation direction of the turntable 2 in the second process area P2. As shown in FIGS. 10 through 12, the plasma generation mechanism 200 includes a injector body 201 made of a housing disposed to extend along a radial direction of the turntable 2, and the injector body 201 is disposed in the proximity of the wafer W on the turntable 2. In the injector body 201, two spaces and having different widths divided along a longitudinal direction by a partition 202 are formed. One of the spaces is a gas activation chamber 203 that is a gas activation passage for causing (activating) plasma generation gas to become plasma. The other of the spaces is a gas introduction chamber 204 that is a gas introduction passage for supplying the plasma generation gas to the gas activation chamber 203.

In FIGS. 10 through 12, 205 denotes a gas introduction nozzle; 206 denotes a gas hole; 207 denotes a gas introduction port; 208 denotes a joint part; and 209 denotes a gas supplying port. In the configuration, the plasma generation gas is supplied to the inside of the gas introduction chamber 204 from the gas hole 206 of the gas introduction nozzle 205, and the gas flows to the gas activation chamber 203 through a cutout 211 formed at a top part of the partition 202. In the gas activation chamber 203, two sheath pipes 201 made from dielectric, for example, ceramic, extend along the partition 202 from a base end side through an extending end side of the gas activation chamber 203. In the inside of the sheath pipes 212, rod-like electrodes 213 are inserted to pass therethrough. Base end sides of the electrodes 213 are drawn to the outside of the injector body 201, and are connected to a high-frequency power source 215 through a matching device 214 on the outside of the vacuum chamber 1. On a bottom surface of the injector body 201, gas discharge holes 221 are arranged in a longitudinal direction of the injector body 201 for discharging downward plasma that has been generated and activated by a plasma generation part 220 that is an area between the electrodes 213. The injector body 201 is disposed to have a state in which an extending end extends toward the center portion of the turntable 2. 231 in FIG. 10 denotes a gas introduction path for introducing the plasma generation gas to the gas introduction nozzle 205; 232 denotes a valve; 233 denotes a flow rate adjustment part; 234 denotes a gas source in which the plasma generation gas is stored. As the plasma generation gas, argon (Ar) gas, oxygen (O₂) gas, nitrogen (N₂) gas or such is used.

Also in this embodiment, similarly, five wafers W are placed on the turntable 2, the turntable 2 is rotated, BTBAS gas, O₃ gas and N₂ gas are supplied toward the wafers W respectively from the respective nozzles 31, 32, 41, 42, and further, as described above, the purge gas is supplied to the center portion area C and the area on the lower side of the turntable 2. Further, power is supplied to the heater unit 7, the plasma generation gas, for example, Ar gas, is supplied to the plasma generation mechanism 200, and further, high-frequency power is supplied to the plasma generation part 220 (the electrodes 213) by the high-frequency power source 215. At this time, the inside of the vacuum chamber 1 is vacuum atmosphere, and therefore, the plasma generation gas flowing to an upper part of the gas activation chamber 203 enters a state in which plasma is generated (activation is carried out) by the high-frequency power, and is supplied to the wafer W through the gas discharge holes 221. Thus, when the wafer W on the turntable 2 passes through the second process area P2, the surface of the wafer W is directly exposed to the plasma supplied by the plasma generation mechanism 200 disposed in the vicinity of the wafer W.

When the plasma has reached the wafer W having passed through the second process area P2 and having the above-described silicon oxide film produced thereon, a carbon component or moisture remaining in the silicon oxide film evaporates and is ejected, or a bond between silicon and oxygen is strengthened. Thus, by providing the plasma generation mechanism, 200, the silicon oxide film is modified in its quality, and it is possible to deposit the silicon oxide film containing a small amount of impurities and having improved bond strength. At this time, by providing the plasma generation mechanism 200 on the downstream side in the rotation direction of the turntable 2, it is possible to apply the plasma to the thin film in a state in which oxidation reaction has sufficiently progressed by the second reaction gas, and thus, it is possible to deposit the silicon oxide film having a more satisfactory film quality.

In this example, Ar gas is used as the plasma generation gas. However, instead of or together with the gas, O₂ gas or N₂ gas may be used. In a case where Ar gas is used, such an effect is obtained that a SiO₂ bond in the film is produced, and a SiOH bond is eliminated. In a case where O₂ gas is used, such an effect is obtained that oxidation is accelerated in a part in which reaction has not been carried out, and C (carbon) in the film is reduced and electric characteristics are improved.

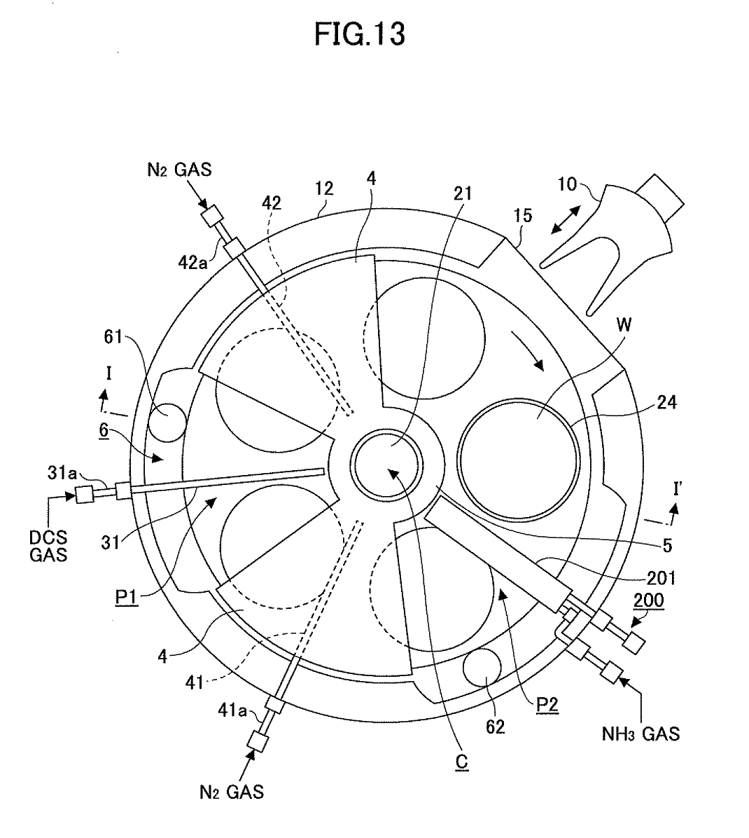

Further, the above-described example is such that the plasma generation mechanism 200 is provided separate from the second gas reaction nozzle 32. However, as shown in FIG. 13, the plasma generation mechanism 200 may also be used as the second reaction gas nozzle. In this example, from the first reaction gas nozzle 31, DCS (dichlorosilane) gas as the first reaction gas is supplied, a process of adsorption of silicon is carried out in the first process area P1, and then, in the second process area P2, NH₃ gas becoming plasma is supplied by the plasma generation mechanism 200 as the second reaction gas. In the second process area P2, reaction of nitriding the silicon by the NH₃ becoming plasma, and modification of a produced silicon nitride film (SiN film) thus obtained from the nitriding process are carried out. Further, by providing a configuration such that TiCl₄ gas is supplied as the first reaction gas from the first reaction gas nozzle 31, NH₃ gas becoming plasma is supplied from the plasma generation mechanism 200 as the second reaction gas, and a TiN film is deposited.

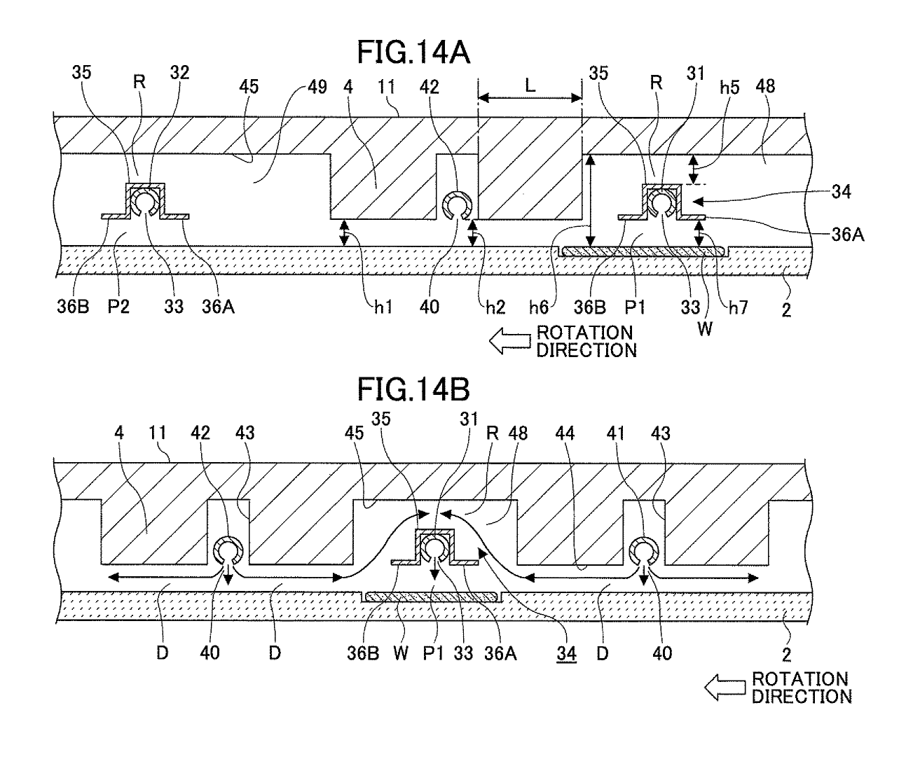

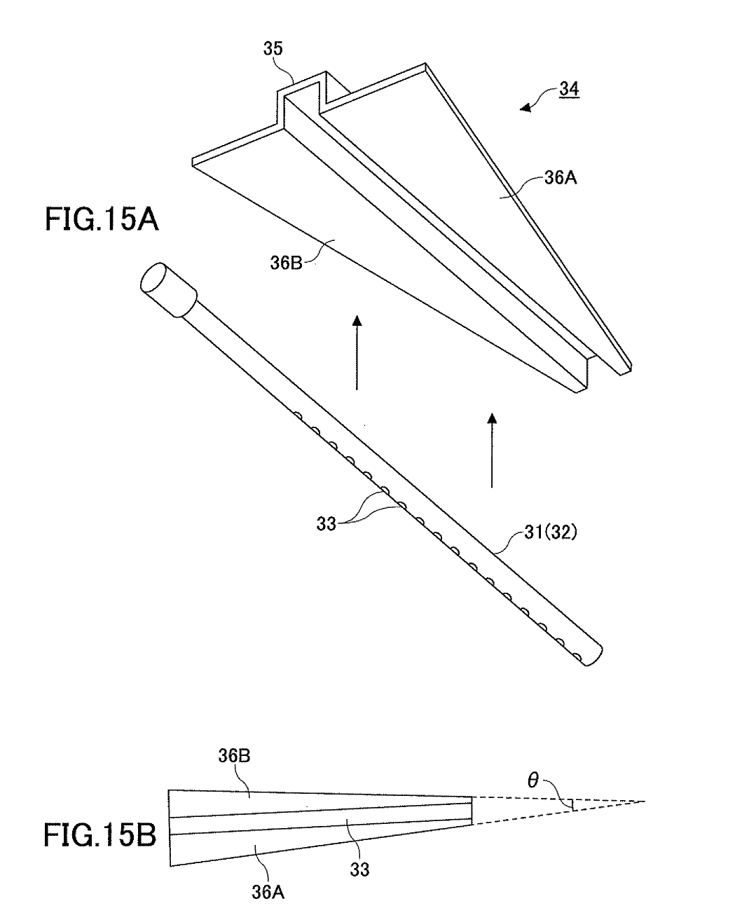

Next, based on FIGS. 14A through 16B, a third embodiment of the present invention will be described. In this embodiment, nozzle covers 34 are provided for the first reaction nozzle 31 and the second reaction nozzle 32. The nozzle covers 34 extend along longitudinal directions of the gas nozzles 31, 32, have base parts 35 having U-shaped longitudinal sections, and upper parts and side parts of the gas nozzles 31, 32 are covered by the base parts 35. Further, flow regulatory plates 36A, 36B protrude in horizontal directions, i.e., on the upstream side and the downstream side in the rotation direction of the turntable 2, from both sides of bottom ends of the base parts 35. As shown in FIGS. 15A and 15B, the flow regulatory plates 36A, 36B are formed to protrude from the base part 35 larger as a position is moved from the side of the center portion toward the side of the circumferential edge of the turntable 2, and are configured to be like a sector in a plan view. In this example, the flow regulatory plates 36A, 36B are formed to be bilaterally symmetrical between both sides about the base part 35, and an angle θ formed by lines shown by broken lines in FIG. 15B extending from contour lines of the flow regulatory plates 36A, 36B (an angle formed by two straight lines of the sector) is, for example, 10 degrees. The angle θ may be designed appropriately in consideration of sizes in the circumferential direction of the separation areas D supplying the N₂ gas, sizes in the circumferential direction of the process areas P1, P2, and, for example, equal to or more than 5 degrees and less than 90 degrees.

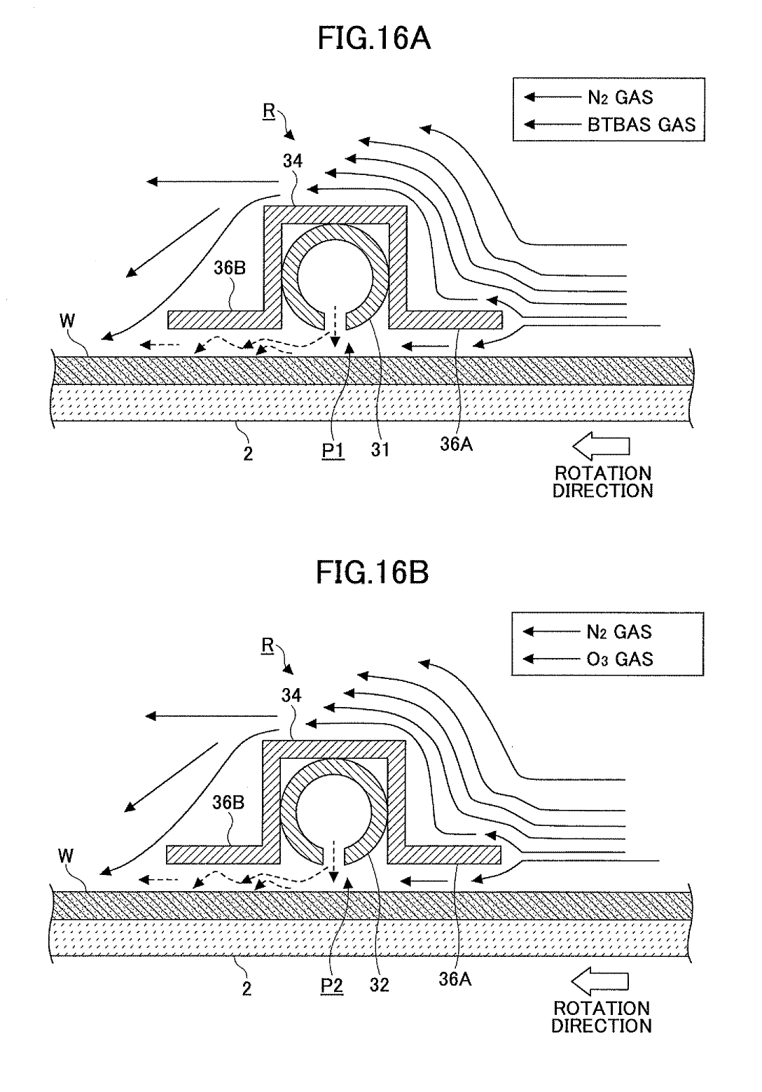

As shown in FIGS. 15A and 15B, the nozzle cover 34 is provided in such a manner that an extending end side (the side on which the width becomes narrower) of the flow regulatory plates 36A, 368 approach the convex portion 4, and also, a rear end side (the side on which the width becomes wider) extends toward the peripheral edge of the turntable 2. Further, the nozzle cover 34 is provided in such a manner that the nozzle cover 34 is apart from the separation area D, and a gap R that is a space through which gas flows is provided between the nozzle cover 34 and the second ceiling surface 45. FIGS. 16A and 16B show flows of respective gases above the turntable 2 by arrows. As shown in FIGS. 16A and 16B, the gap R acts as a flow passage of N₂ gas flowing toward the process areas P1, P2 from the separation area D.

A height h5 of the gaps R in the first and second process areas P1, P2 shown in FIGS. 14A and 14B is, for example, 10 mm through 70 mm. Further, a height h6 from the surfaces of the wafers W to the second ceiling surfaces 45 in the first and second process areas P1, P2 shown in FIGS. 14A and 14B is, for example, 15 mm through 100 mm, and for example, 32 mm. The height h5 of the gap R and the height h6 may be changed appropriately depending on process conditions such as kinds of the gases. The height h5 of the gaps R and the height h6 are set such that a regulatory function of the nozzle covers 35 for preventing the separation gas from flowing into the process areas P1, P2 by guiding the separation gas to the gap R becomes effective as much as possible. In order to obtain the regulatory effect, it is preferable that the height h5 is equal to or more than heights between the turntable 2 and the bottom ends of the gas nozzles 31, 32. Further, the heights of the gaps R may be set such that the height of the gap R is larger in the second process area P2 than the first process area P1. In this case, the height of the gap R in the first process area P1 is set to, for example, 10 mm through 100 mm, and the height of the gap R in the second process area P2 is set to, for example, 15 mm through 150 mm.

Further, as shown in FIGS. 14A and 14B, bottom surfaces of the flow regulatory plates 36A, 365 of the nozzle covers 34 are formed at heights approximately the same as bottom ends of ejection holes 33 of the reaction gas nozzles 31, 32. In the figures, a height of the flow regulatory plates 36A, 36B from the surface of the turntable 2 (the surfaces of the wafers W) indicated as h7 is 0.5 mm through 4 mm. It is noted that the height h7 is not limited to 0.5 mm through 4 mm. The height h7 may be set to a height such that N₂ gas is guided to the gap R as mentioned above, and gas concentrations of the reaction gases in the process areas P1, P2 are ensured to have sufficient concentrations such that the processes of the wafers W can be carried out. The height h7 may also be, for example, 0.2 mm through 10 mm. As will be described later, the flow regulatory plates 36A, 36B of the nozzle covers 34 have a role to reduce flow rates of N₂ gas supplied from the separation areas D and entering the lower side of the reaction nozzles 31, 32, and also, prevent BTBAS gas and O₃ has respectively supplied by the reaction gas nozzles 31, 32 from rising from the surface of the turntable 2. As long as the role can be played, the positions at which the flow regulatory plates 36A, 36B are provided are not limited to those mentioned above.

FIGS. 16A, 16B show flows of N₂ gas around the first and second reaction gas nozzles 31, 32 by arrows of solid lines. In the process areas P1, P2 below the reaction gas nozzles 31, 32, BTBAS gas and O₃ gas are discharged, and flows thereof are indicated by arrows of broken lines. Rising of the discharged BTBAS gas (O₃ gas) from the lower side to the upper side of the flow regulatory plates 36A, 36B is controlled by the flow regulatory plates 36A, 36B. Therefore, an area below the flow regulatory plates 36A, 36B has a pressure higher than an area above the flow regulatory plates 36A, 36B. Flows of N₂ gas flowing from the upstream side in the rotation direction toward the reaction gas nozzles 31, 32 are controlled by this pressure difference and also the flow regulatory plate 36A protruding to the upstream side in the rotation direction. Thereby, the N₂ gas is prevented from flowing downward into the process areas P1, P2 and flows toward the downstream side. Thus, the N₂ gas passes through the gaps R provided between the nozzle covers 34 and the ceiling surfaces 45 and flows toward the downstream sides of the reaction gas nozzles 31, 32 in the rotation direction. That is, the flow regulatory plates 36A, 36B are disposed at positions such that most of the N₂ gas flowing from the upstream sides to the downstream sides of the reaction gas nozzles 31, 32 can detour around the lower sides of the reaction gas nozzles 31, 32 and be guided to the gaps R. Accordingly, amounts of N₂ gas flowing into the first and second process areas P1, P2 can be controlled.

Further, pressures in the downstream sides (rear sides) are lower in comparison to the upstream sides (front sides) of the reaction gas nozzles 31, 32 receiving the gas. Thereby, N₂ gas flowing into the first process area P1 is about to rise toward a position on the downstream side of the reaction gas nozzle 31. Along therewith, BTBAS gas discharged from the reaction gas nozzle 31 and flowing toward the downstream side in the rotation direction is also about to rise from the turntable 2. However, as shown in FIG. 16A, by the flow regulatory plate 36B provided on the downstream side in the rotation direction, the BTBAS gas and the N₂ gas are prevented from rising. Then, the BTBAS gas and the N₂ gas flow to the downstream side between the flow regulatory plate 36B and the turntable 2. Then, on the downstream side in the process area P1, the BTBAS gas and the N₂ gas flow together with N₂ gas having passed through the gap R above the reaction gas nozzle 31 and having flowed to the downstream side.

Then, the BTBAS gas and the N₂ gas are pressed by N₂ gas flowing toward the upstream side from the separation gas nozzle positioned on the downstream side of the process area P1 and are prevented from entering the lower side of the convex portion 4 in which the separation gas nozzle is provided. Then, the BTBAS gas and the N₂ gas are ejected from the evacuation port 61 through the evacuation area 6 together with N₂ gas from the separation gas nozzles 41, 42 and N₂ gas discharged from the center portion area C.

In this embodiment, the gaps R are provided which act as passages of N₂ gas flowing from the upstream side to the downstream side in the rotation direction of the turntable 2 from the separation areas D, above the reaction gas nozzles 31, 32 provided above the turntable 2 on which the wafers W are placed. Further, the nozzle covers 34 including the flow regulatory plates 36A that protrude to the upstream sides in the rotation direction are provided to the first and second process areas 21, P2. By the flow regulatory plates 36A, most of N₂ gas flowing to the sides of the first and second process areas P1, P2 from the separation areas D in which the separation gas nozzles 41, 42 are provided flows to the downstream sides of the first and second process areas P1, 22 through the gaps R, and flows into the evacuation ports 61, 62. Thereby, the above-mentioned most of the N₂ gas is prevented from flowing to the lower sides of the first and second reaction gas nozzles 31, 32. Accordingly, concentrations of BTBAS gas and O₃ gas in the first and second process areas 21, 22 are prevented from being lowered. As a result, even when the rotation speed of the turntable 2 is increased, molecules of BTBAS gas can be positively caused to adsorb on the wafers in the first process area 21, and thus, it is possible to carry out proper film deposition. Further, in the second process area P2, lowering of concentration of O₃ gas can be prevented, and thus, it is possible to carry out oxidation of BTBAS sufficiently, and to deposit a film having a small amount of impurities. Accordingly, even when the rotation speed of the turntable 2 is increased, it is possible to carry out film deposition on the wafers W with high uniformity, film quality is improved, and it is possible to carry out a satisfactory film deposition process.

The nozzle cover 34 may be provided to only any one of the reaction gas nozzles 31, 32, and, may be provided to the plasma generation mechanism 200. Further, the flow regulatory plates 36A, 36B of the nozzle covers 34 may be provided to only the upstream sides in the rotation direction of the reaction gas nozzles 31, 32, and, may be provided to only the downstream sides in the rotation direction of the reaction gas nozzles 31, 32. Further, to the reaction gas nozzles 31, 32, flow regulatory plates may be provided to protrude on the upstream sides and the downstream sides in the rotation direction from the bottom ends of the reaction gas nozzles, without providing the base parts 35. Further, the shapes of flow regulatory plates in a plan view are not limited to the sector shapes.

As the first reaction gas applied to the present invention, other than the above-described examples, DCS [dichlorosilane], HCD [hexachlorodisilane], TMA [Trimethyl Aluminum], 3DMAS [tris(dimethyl amino) silane], Ti(MPD)(THD) [(methyl-pentadionate)(bis-tetra-methyl-heptandionate) titanium], monoamino-silane, or such may be cited. As the second reaction gas, in a case where an oxidation process is carried out, other than O₃ gas, H₂O₂ gas or such may be used, and, in a case where a nitriding process is carried out, other than NH₃ gas, N₂ gas or such may be used. Further, the present invention may be applied to a case where a High-K film (high dielectric constant layer insulating film) is deposited, where, as the first reaction gas, TEMAZ [tetrakis-ethyl-methyl-amino-zirconium], TEMAH [tetrakis-ethyl-methyl-amino-hafnium], or Sr(THD)₂ [bis(tetra methyl heptandionate) strontium] is used, and, as the second reaction gas, O₃ gas or NH₃ gas is used. Further, the present invention may be applied to a case where a metal film such as aluminum oxide (Al₂O₃), titanium oxide (TiO) or such is deposited, where, as the first reaction gas, Trimethyl Aluminum (TMA) or (methyl-pentadionate)(bis-tetra-methyl-heptandionate) titanium (Ti(MPD)(THD)) is used, and, as the second reaction gas, O₃ gas is used. Further, according to the present invention, the number of the first process area P1 is not limited to one, and may be two or more. Further, the number of the second process area P2 is not limited to one, and may be two or more. Further, for one first process area P1, plural second process areas P2 may be provided, and in this case, a case where one of the second process areas P2 has an area smaller than the first process area P1, but a total area of the plural second process areas P2 is larger than the first process area P1 is included in the scope of the present invention.

Further, in the ceiling surfaces 44 of the separation areas D, parts on the upstream sides in the rotation direction with respect to the separation nozzles 41, 42 may preferably be such that a width along the rotation direction of a part becomes larger as the part is positioned more to the peripheral edge. The reason therefor is that, because of rotation of the turntable 2, a flow of gas that flows toward the separation area D from the upstream side is higher as the flow approaches the peripheral edge more closely. From this viewpoint, it is advantageous that, as described above, the convex portions 4 are configured to have sector shapes.

Further, according to the present invention, separation gas supplying portions are not limited to have a configuration in which the convex portions 4 are disposed on both sides of the separation gas nozzles 41, 42. A configuration may be adopted in which in the insides of the convex portions 4, passage chambers for the separation gas are formed to extend in directions of diameters of the turntable 2, and many ejection holes are bored in a longitudinal directions on bottom surfaces of the passage chambers.

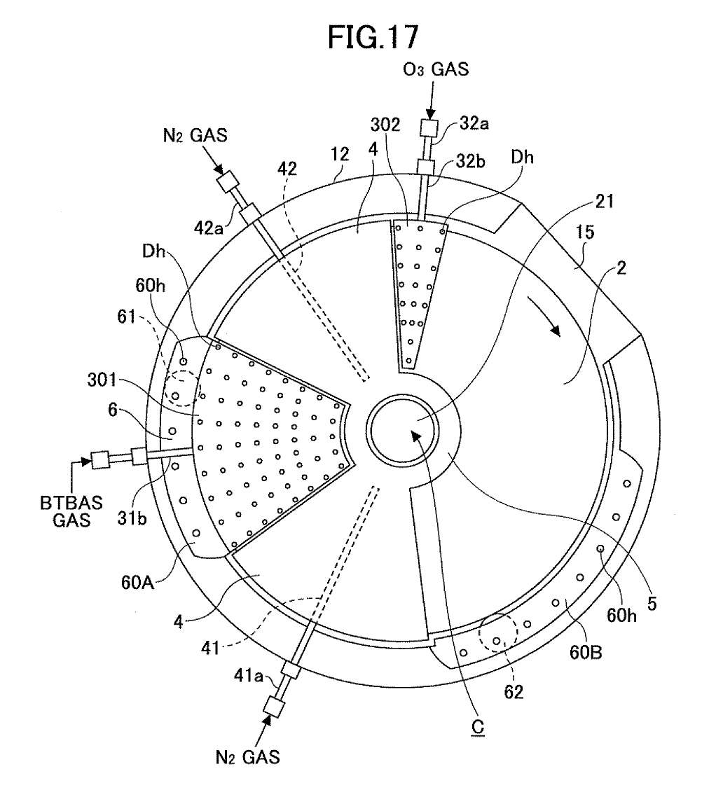

Further, according to the present invention, as reaction gas supplying portions, showerheads may be used. The showerheads are disposed between the mutually adjacent separation areas D, and have sector shapes in which the rotation center of the turntable 2 is pivots of the sectors. Further, the showerhead has plural gas ejection holes that cover the substrate placed on the turntable 2 when the substrate passes through the lower side of the showerhead. FIG. 17 shows an example in which the showerheads and baffle plate (described later) are provided. As shown in FIG. 17, instead of the first reaction gas nozzle 31, a showerhead 301 having plural gas ejection holes Dh bored for discharging BTBAS gas toward the surface of the wafer W placed on the turntable 2 is provided. Further, instead of the second reaction gas nozzle 32, a showerhead 302 having plural gas ejection holes Dh bored for discharging O₃ gas toward the surface of the wafer W placed on the turntable 2 is provided. In order to supply BTBAS gas and O₃ gas to the showerheads 301 and 302, respectively, supplying pipes 31b and 32b are provided to pass through the circumferential wall of the chamber body 12. BTBAS gas is supplied from the supplying pipe 31b to the showerhead 301, and thereby, the BTBAS gas is discharged toward the surface of the wafer W placed on the turntable 2. O₃ gas is supplied from the supplying pipe 32b to the showerhead 302, and thereby, the O₃ gas is discharged toward the surface of the wafer W placed on the turntable 2.

Further, baffle plates may be provided to surround the peripheral edge part of the turntable 2, and openings or slits may be formed in the baffle plates. In the example shown in FIG. 17, baffle plates 60A and 60B are provided to surround the edge part of the turntable 2, and openings 60h are formed in the baffle plates 60A, 60B. In the example of FIG. 17, in outer circumferential directions of the turntable 2, gases ejected from between the peripheral edge part of the turntable 2 and the peripheral edge of the inner circumferential wall of the vacuum chamber 1 are ejected by the above-mentioned vacuum evacuation mechanism from the evacuation ports 61, 62 provided in the outside of the turntable 2 through the openings 60h of the baffle plates 60A and 60B. In this case, as a result of the openings (or slits) 60h provided in the baffle plates 60A, 60B being opened to be sufficiently small, the separation gas supplied to the separation areas D flows substantially in the direction of the process areas P1, P2, and then flows in the direction of the evacuation ports 61, 62.

Further, according to the present invention, a reaction precursor material containing metal may be used as the first reaction gas, and an oxidation gas which reacts with the first reaction gas and depositing a film of metal oxide or a gas containing nitrogen which reacts with the first reaction gas and depositing a film of metal nitride may be used as the second reaction gas.

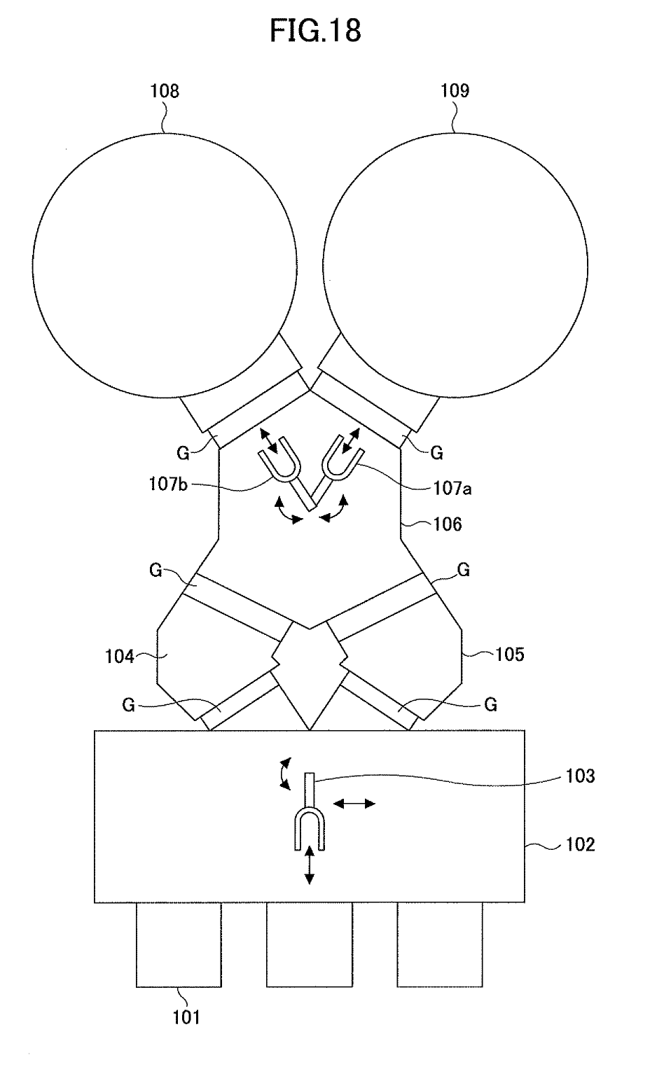

A substrate processing apparatus using the film deposition apparatus described above is shown in FIG. 18. In FIG. 18, 101 denotes a hermetically sealed transfer chamber called a hoop holding, for example, 25 wafers. 102 denotes an atmospheric transfer chamber in which a transfer arm 103 is disposed. 104, 105 denote load lock chambers (preliminary vacuum chambers) whose atmosphere is changeable between atmospheric atmosphere and vacuum atmosphere. 106 denotes a vacuum transfer chamber in which two transfer arms 107a, 107b are provided. 108, 109 denote the film deposition apparatuses according to the present invention. The transfer chamber 101 is transferred to a transfer-in transfer-out port including a placing table not shown, and is connected to the atmospheric chamber 102, and after that, a lid of the transfer chamber 101 is opened by an opening/closing mechanism not shown, and a wafer is taken out from the transfer chamber 101 by the transfer arm 103. Next, the wafer is transferred into the inside of the load lock chamber 104 (105), the inside of the load lock chamber is switched from atmospheric atmosphere to vacuum atmosphere, and after that, the wafer is taken out by the transfer arm 107, the wafer is transferred into one of the film deposition apparatuses 108, 109, and the above-described film deposition process is carried out. Thus, by providing the plural, for example, two film deposition apparatuses according to the present invention for processing, for example, five wafers each, it is possible to carry out so-called ALD (MLD) with high throughput.

### Evaluation Experiment 1

In order to confirm the advantageous effects of the present invention, a simulation by a computer was carried out. First, the film deposition apparatus according to the embodiment shown in FIGS. 1 through 8 was set by the simulation. At this time, the following sizes were set. That is, a diameter of the turntable 2 was set to 960 mm; the convex portion 4 was set to have a length in a circumferential direction at a part of a boundary between the convex portion 4 and the protrusion portion 5 away from the rotation center by 140 mm of, for example, 146 mm; the convex portion 4 was set to have a length in a circumferential direction at the outermost part of the wafer placing area of, for example, 502 mm. Further, for the first process area P1, the following settings were carried out. That is, a length in a circumferential direction at a part of boundary between the first process area P1 and the protrusion portion 5 away from the rotation center by 140 mm was set to 146 mm; and a length in a circumferential direction at the outermost part of the wafer placing area was set to 502 mm. Further, for the second process area P2, the following settings were carried out. That is, a length in a circumferential direction at a part of boundary between the second process area P2 and the protrusion portion 5 away from the rotation center by 140 mm was set to 438 mm; and a length in a circumferential direction at the outermost part of the wafer placing area was set to 1506 mm. Further, the following settings were carried out. That is, the height h1 of the bottom surface of the convex portion 4 from the surface of the turntable 2 was set to 4 mm; and the gap SD between the turntable 2 and the inner circumferential wall of the vacuum chamber 1 in the separation area D was set to 10 mm. Furthermore, the height h2 of the ceiling surfaces 45 of the process areas P1, P2 from the surface of the turntable 2 was set to, for example, 26 mm. The height h3 of the top surfaces of the reaction nozzles 31, 32 from the ceiling surfaces 45 was set to 11 mm; and the height h4 of the bottom surfaces of the reaction nozzles 31, 32 from the turntable 2 was set to 2 mm.

Further, BTBAS gas was used as the first reaction gas and O₃ gas was used as the second reaction gas. Supplying amounts thereof were set as follows: That is, a supplying amount of BTBAS gas was set to 300 sccm. Because O₃ gas was supplied from a gas organizer, a supplying amount of O₂ gas O₃ gas was set to 10 slm, and, an O₃ generation amount was set to 200 g/Nm³. Further, as the separation gas and the purge gas, N₂ gas was used, and a total supplying flow rate thereof was set to 89 slm. A breakdown thereof was: the separation gas nozzles 41, 42: each 25 slm; the separation gas supplying pipe 51: 30 slm; the purge gas supplying pipe 72: 3 μm; and the others: 6 slm. As the process conditions, the processing pressure was set to 1.33 kPa (10 Torr); and the processing temperature was set to 300° C. Then, a concentration distribution of the N₂ gas was simulated.

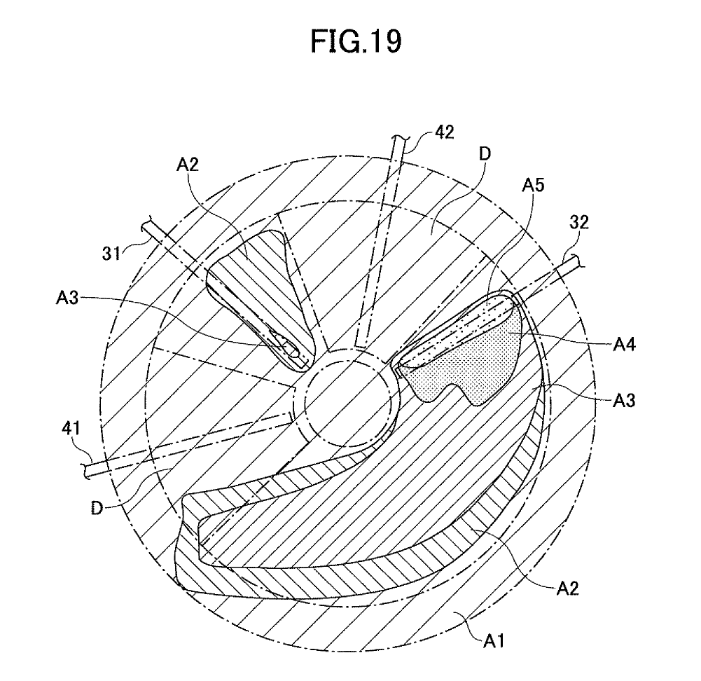

A simulation result is shown in FIG. 19. An actual simulation result was output by a color screen to display a concentration distribution of N₂ (unit: %) in a manner of gradation by computer graphics. However, for the sake of convenience of showing a drawing, FIG. 19 shows a general concentration distribution. Therefore, the actual concentration distribution in the figure was not discrete, and FIG. 19 shows that a steep concentration distribution exists between zones divided by an iso-concentration contour. In FIG. 19, a zone A1: nitrogen concentration is equal to or more than 95%; a zone A2: nitrogen concentration is 65% through 95%; a zone A3: nitrogen concentration is 35% through 65%; a zone A4: nitrogen concentration is 15% through 35%; and a zone A5: nitrogen concentration is equal to or less than 15%. Further, in areas in the proximity to the first and second gas nozzles 31, 32, nitrogen concentration for each reaction gas is shown.

From the result, it is seen that although nitrogen concentration drops in the proximity to the reaction gas nozzles 31, 32, nitrogen concentration is equal to or more than 95% in the separation areas D, and separation of the first and second reaction gases are positively carried out by the separation areas D. Further, in the first and second process areas P1, P2, it is seen that although nitrogen concentration is low in the proximity to the reaction gas nozzles 31, 32, nitrogen concentration increases toward the downstream side in the rotation direction of the turntable 2, and nitrogen concentration becomes equal to or more than 95% in the separation area D adjacent to the downstream side. Therefrom, it is seen that nitrogen gas is ejected to the respective ejection ports 61, 62 through the process areas P1, P2 together with the reaction gases. Further, in the second process area P2, a state is seen in which gas flows from the second reaction gas nozzle 32 provided on the upstream side in the rotation direction of the process area P2 toward the ejection port 62 provided on the downstream side in the rotation direction of the process area P2, and it has been confirmed that the reaction gas reaches throughout the second process area P2 having the large area.

### Evaluation Experiment 2

A film deposition process was actually carried out by using the film deposition apparatus in the embodiment shown in FIG. 1 through 8, and a film thickness of a thus-deposited thin film was measured. The configuration at this time is the same as that set in the (Evaluation Experiment 1). Film deposition conditions are as follows:

First reaction gas (BTBAS gas): 100 sccm

Second reaction gas (O₃ gas): 10 slm (approximately 200 g/Nm³)

Separation gas and purge gas: N₂ gas (total supplying flow rate: 73 slm. A breakdown thereof is: separation gas nozzles 41: 14 slm; separation gas nozzles 42: 18 slm; separation gas supplying pipe 51: 30 slm; purge gas supplying pipe 72: 5 slm; and the others: 6 slm)

Processing pressure: 1.06 kPa (8 Torr)

Processing temperature: 350° C.

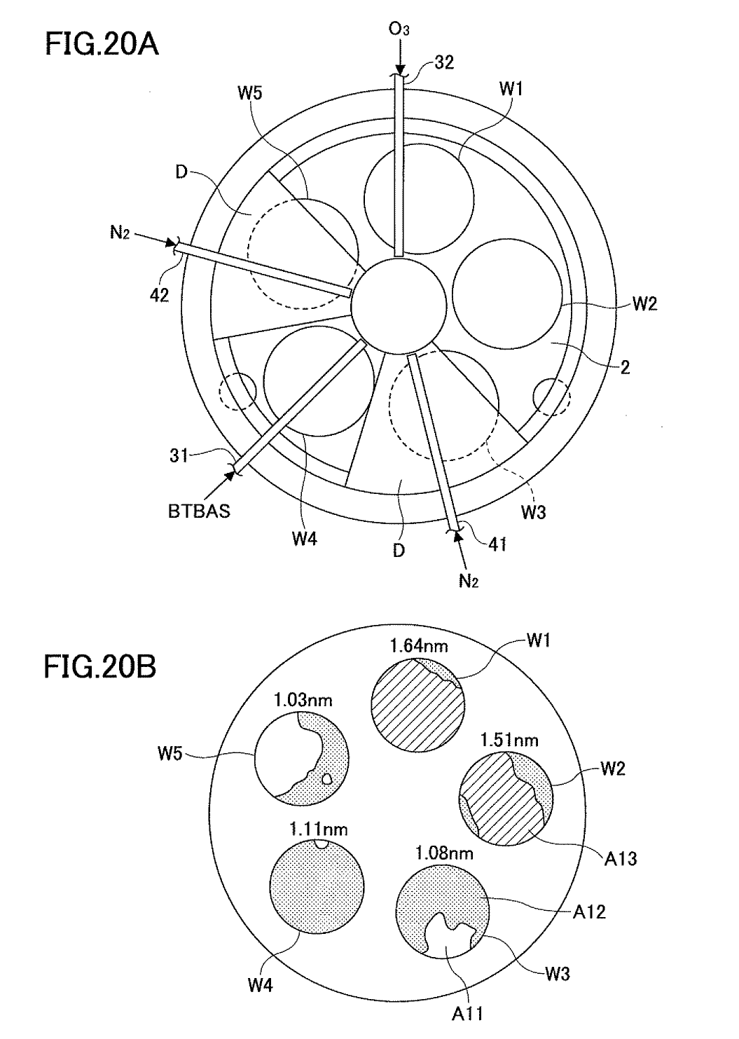

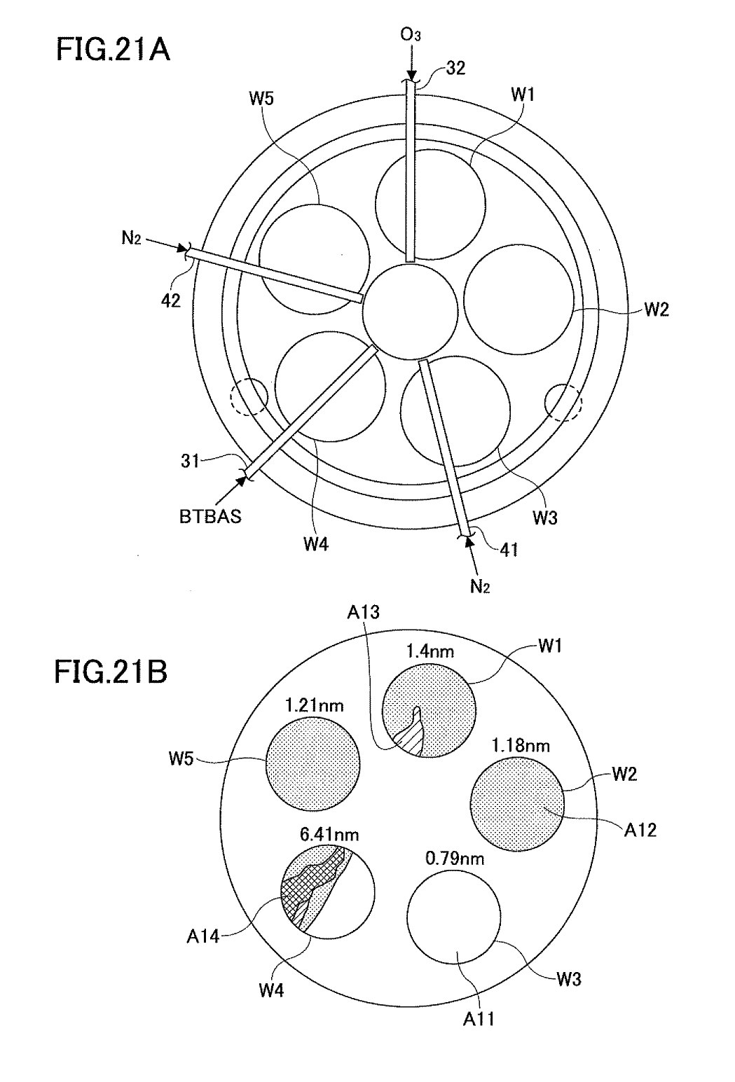

Further, wafers W were placed in the five concave portions 24, respectively, the turntable 2 was not rotated and the processes were carried out for 30 minutes, and after that, film thickness were measured for the five wafers W, respectively. FIGS. 20A and 20B show the result. It is noted that an initial film thickness of a thin film is 0.9 nm. Further, also in a configuration in which the convex portions 4 were not provided, the same processes were carried out. FIGS. 21A and 21B show the result.

In FIGS. 20A, 20B and FIGS. 21A, 21B, film thicknesses of the respective wafers W are shown, and also, film thickness distributions are simply shown by a gradation of four stages. The area having the smallest film thickness is A11; the area having a film thickness next to the smallest film thickness is A12; the area having a film thickness further next but one to the smallest film thickness is A13; and the area having the largest film thickness is A14. From the result, a local increase in film thickness is seen at the wafer W4 placed in an area to which BTBAS gas is supplied, and it is presumed that O₃ gas reaches the area to which BTBAS gas is supplied. In contrast thereto, in the configuration in which the convex portions 4 are provided, occurrence of an abnormal film deposition such as a local increase in film thickness or such is not seen, and it can be seen that separation of BTBAS gas and O₃ gas is carried out by N₂ gas. Thus, by using the film deposition apparatus according to the present invention, it is presumed that satisfactory film deposition can be carried out according to the ALD method.

What is claimed is:

1. A film deposition apparatus in which, in a vacuum chamber, a turntable on which plural substrates are placed is rotated, the plural substrates in sequence come into contact with plural reaction gases supplied to plural process areas, and thin films are deposited on surfaces of the plural substrates, the film deposition apparatus comprises:
plural reaction gas supplying portions that are provided in the plural process areas, face a proximity of the plural substrates which are revolving, and supply the plural reaction gases respectively in directions of the plural substrates;
a separation gas supplying portion that supplies in a separation area which is provided between the plural process areas a separation gas for preventing the plural reaction gases supplied to the plural process areas from reacting; and
an evacuation mechanism in which evacuation ports are provided in areas corresponding to peripheral directions of the turntable in the outsides of respective ones of the plural process areas, the plural reaction gases supplied to the plural process areas and the separation gas supplied to the separation area are introduced to the evacuation port via the process areas and are ejected in communication with the evacuation ports, wherein
the plural process areas includes
a first process area in which a process of causing a first reaction gas to adsorb on the surfaces of the plural substrates is carried out, and
a second process area, having an area larger than the first process area, in which a process of causing the first reaction gas having adsorbed on the surfaces of the plural substrates and a second reaction gas to react, and depositing the films on the surfaces of the plural substrates, is carried out.

2. The film deposition apparatus as claimed in claim 1, wherein
a reaction gas supplying portion is provided to supply the second reaction gas to a first half part along a direction of rotation of the turntable in the second process area.

3. The film deposition apparatus as claimed in claim 1, wherein
a plasma generating part is provided to carry out surface modification of the plural substrates on which the films have been deposited in the second process area, in a second half part along the direction of rotation of the turntable in the second process area.

4. The film deposition apparatus as claimed in claim 3, wherein
the plasma generating part is disposed in the proximity of the plural substrates placed on the turntable, and directly exposes the surfaces of the plural substrates to the plasma generated by the plasma generating part when the plural substrates placed on the turntable pass through the second process area.

5. The film deposition apparatus as claimed in claim 1, wherein
a rotation-center-supplying separation gas supplying portion is provided to supply a separation gas from a rotation center of the turntable to the inside of the vacuum chamber, and
the separation gas supplied from the rotation center is ejected from the evacuation port via the plural process areas.

6. The film deposition apparatus as claimed in claim 1, wherein
the separation gas flowing into the plural process areas from the separation area is ejected from the evacuation port via between the plural reaction gas supplying portions that are provided as being separated from ceilings of the process areas respectively and the ceilings.

7. The film deposition apparatus as claimed in claim 1, wherein
a gap between the turntable and a side wall of the vacuum chamber is set narrower in the outside of the separation area than the outside of the plural process areas in a peripheral direction of the turntable of the separation area, and most of the separation gas supplied from the separation area flows toward the plural process areas via the separation area.

8. The film deposition apparatus as claimed in claim 1, wherein
a transfer opening through which the plural substrates are transferred into the vacuum chamber and the plural substrates are transferred out of the vacuum chamber is provided to face the second process area having the larger area.

9. The film deposition apparatus as claimed in claim 1, wherein
the plural processing gas supplying portions are disposed to face a rotation center of the turntable, and are injectors having plural blowout openings disposed linearly, or are showerheads disposed between the separation areas, having arc shapes having pivots at the rotation center of the turntable and having plural gas blowout openings that cover the plural substrates when the plural substrates placed on the turntable pass the showerheads.

10. The film deposition apparatus as claimed in claim 1, wherein
in peripheral directions of the turntable, gas that is ejected from a gap between an edge of the turntable and a side wall of the vacuum chamber is ejected by the evacuation mechanism via an opening or a slit provided in a baffle plate that surrounds the edge of the turntable, and also, the separation gas supplied to the separation area flows in a direction of the evacuation port after flowing substantially in directions of the plural process areas as a result of the opening or the slit being made to open to be sufficiently small.

11. The film deposition apparatus as claimed in claim 1, wherein
the first reaction gas comprises a reaction precursor containing metal, and the second reaction gas comprises an oxidation gas which reacts with the first reaction gas and depositing a film of metal oxide or a gas containing nitrogen which reacts with the first reaction gas and depositing a film of metal nitride.

12. The film deposition apparatus as claimed in claim 1, wherein
in the second process area to which the second reaction gas is supplied and having an area larger than the first process area to which the first reaction gas is supplied, the plural substrates pass in the second reaction gas while surface reaction is carried out.
